(19) United States
(12) Patent Application Publication
(10) Pub. No.: US 2026/0006954 A1
(43) Pub. Date: Jan. 1, 2026

(54) DISPLAY PANEL AND MANUFACTURING METHOD THEREOF, AND DISPLAY DEVICE

(71) Applicant: Tianma Advanced Display Technology Institute (Xiamen) Co.,Ltd., Xiamen (CN)

(72) Inventors: Wei HE, Xiamen (CN); Yangui FENG, Xiamen (CN); Dexiao HUANG, Xiamen (CN); Ying LIU, Xiamen (CN)

(21) Appl. No.: 18/886,468

(22) Filed: Sep. 16, 2024

(30) Foreign Application Priority Data
Jun. 27, 2024 (CN) 202410850948.X

(51) Int. Cl. H01L 33/52; H01L 25/16; H01L 33/58

(52) U.S. Cl. CPC H10H 20/852; H01L 25/167; H10H 20/855; H10H 20/0362; H10H 20/0363

(57) ABSTRACT

A display panel, a method for manufacturing a display panel, and display device are provided. The display panel includes a driving substrate and a light-emitting element disposed on a side of the driving substrate. The light-emitting element includes a light-emitting element body and a protection structure. The protection structure contacts and covers a light-emitting surface of the light-emitting element body. The light-emitting surface includes a first light-emitting surface and/or a side light-emitting surface. The first light-emitting surface is a surface of the light-emitting element body away from the driving substrate. A plane where the side light-emitting surface is located intersects with a plane where the first light-emitting surface is located. The protection structures of at least a portion of the light-emitting elements are independently disposed.

### CROSS-REFERENCE TO RELATED APPLICATION

The present disclosure claims priority of Chinese Patent Application No. 202410850948.X, filed on Jun. 27, 2024, the entire content of which is hereby incorporated by reference.

### FIELD OF THE DISCLOSURE

The present disclosure generally relates to the field of display technology and, more particularly, relates to a display panel and a manufacturing method thereof, and a display device.

### BACKGROUND

With the development of display technology, display products exhibit a diversified development trend. Micro-light-emitting components are increasingly used in display products due to their advantages of high brightness, high contrast and high reliability. When a micro light-emitting element display device is in operation, due to the presence of ambient light and the high reflectivity of light-emitting elements and metal wirings in the backplane, contrast of displayed images may decrease, and viewing experience of users may be affected.

In existing technology, to reduce light reflection by light-emitting elements and metal wirings, light-shielding materials may be used to shield metal wirings. However, in existing technology, the light-shielding material may remain on light-emitting surfaces of the light-emitting elements, and light-emitting efficiency of the light-emitting elements may thus be affected.

### SUMMARY

One aspect of the present disclosure includes a display panel. The display panel includes a driving substrate and a light-emitting element disposed on a side of the driving substrate. The light-emitting element includes a light-emitting element body and a protection structure. The protection structure contacts and covers a light-emitting surface of the light-emitting element body. The light-emitting surface includes a first light-emitting surface and/or a side light-emitting surface. The first light-emitting surface is a surface of the light-emitting element body away from the driving substrate. A plane where the side light-emitting surface is located intersects with a plane where the first light-emitting surface is located. The protection structures of at least a portion of the light-emitting elements are independently disposed.

Another aspect of the present disclosure includes a method for manufacturing a display device. The method includes providing a driving substrate, and transferring a light-emitting element to a side of the driving substrate. The light-emitting element includes a light-emitting element body and a protection structure. The protection structure contacts and covers a light-emitting surface of the light-emitting element body. The light-emitting surface includes a first light-emitting surface and/or a side light-emitting surface. The first light-emitting surface is a surface of the light-emitting element body away from the driving substrate. A plane where the side light-emitting surface is located intersects with a plane where the first light-emitting surface is located. The protection structures of at least a portion of the light-emitting elements are independently disposed.

Another aspect of the present disclosure includes a display device. The display device includes a display panel. The display panel includes a driving substrate and a light-emitting element disposed on a side of the driving substrate. The light-emitting element includes a light-emitting element body and a protection structure. The protection structure contacts and covers a light-emitting surface of the light-emitting element body. The light-emitting surface includes a first light-emitting surface and/or a side light-emitting surface. The first light-emitting surface is a surface of the light-emitting element body away from the driving substrate. A plane where the side light-emitting surface is located intersects with a plane where the first light-emitting surface is located. The protection structures of at least a portion of the light-emitting elements are independently disposed.

Other aspects of the present disclosure may be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural diagram of a display panel consistent with the disclosed embodiments of the present disclosure;

FIG. 2 illustrates a cross-sectional structural diagram along A-A′ in FIG. 1, consistent with the disclosed embodiments of the present disclosure;

FIG. 3 illustrates a partial cross-sectional structural diagram of a display panel consistent with the disclosed embodiments of the present disclosure;

FIG. 4 illustrates a schematic structural diagram of another display panel consistent with the disclosed embodiments of the present disclosure;

FIG. 5 illustrates a cross-sectional structural diagram along B-B′ in FIG. 4, consistent with the disclosed embodiments of the present disclosure;

FIG. 6 illustrates a schematic diagram of light propagation consistent with the disclosed embodiments of the present disclosure;

FIG. 7 illustrates a partial cross-sectional structural diagram of another display panel consistent with the disclosed embodiments of the present disclosure;

FIG. 8 illustrates a partial cross-sectional structural diagram of another display panel consistent with the disclosed embodiments of the present disclosure;

FIG. 9 illustrates another schematic diagram of light propagation consistent with the disclosed embodiments of the present disclosure;

FIG. 10 illustrates a schematic structural diagram of a light-emitting element consistent with the disclosed embodiments of the present disclosure;

FIG. 11 illustrates another schematic diagram of light propagation consistent with the disclosed embodiments of the present disclosure;

FIG. 12 illustrates a partial cross-sectional structural diagram of another display panel consistent with the disclosed embodiments of the present disclosure;

FIG. 13 illustrates a partial cross-sectional structural diagram of another display panel consistent with the disclosed embodiments of the present disclosure;

FIG. 14 illustrates a partial cross-sectional structural diagram of another display panel consistent with the disclosed embodiments of the present disclosure;

FIG. 15 illustrates a schematic structural diagram of another display panel consistent with the disclosed embodiments of the present disclosure;

FIG. 16 illustrates a cross-sectional structural diagram along C-C′ in FIG. 15, consistent with the disclosed embodiments of the present disclosure;

FIG. 17 illustrates a schematic structural diagram of another light-emitting element consistent with the disclosed embodiments of the present disclosure;

FIG. 18 illustrates a flowchart of a method for manufacturing a display panel consistent with the disclosed embodiments of the present disclosure;

FIG. 19 illustrates a schematic diagram of the method illustrated in FIG. 18, consistent with the disclosed embodiments of the present disclosure;

FIG. 20 illustrates a flowchart of a process for fabricating a light-transmitting protection structure, consistent with the disclosed embodiments of the present disclosure;

FIG. 21 illustrates a schematic diagram of the process illustrated in FIG. 20, consistent with the disclosed embodiments of the present disclosure;

FIG. 22 illustrates a flowchart of a process for fabricating another light-transmitting protection structure, consistent with the disclosed embodiments of the present disclosure;

FIG. 23 illustrates a schematic diagram of the process illustrated in FIG. 22, consistent with the disclosed embodiments of the present disclosure;

FIG. 24 illustrates a flowchart of a process for fabricating another light-transmitting protection structure, consistent with the disclosed embodiments of the present disclosure;

FIG. 25 illustrates a schematic diagram of the process illustrated in FIG. 24, consistent with the disclosed embodiments of the present disclosure;

FIG. 26 illustrates a flowchart of a method for manufacturing another display panel, consistent with the disclosed embodiments of the present disclosure;

FIG. 27 illustrates is a schematic diagram of the method illustrated in FIG. 26, consistent with the disclosed embodiments of the present disclosure;

FIG. 28 illustrates a flowchart of a method for manufacturing another display panel, consistent with the disclosed embodiments of the present disclosure;

FIG. 29 illustrates a schematic diagram of the method illustrated in FIG. 28, consistent with the disclosed embodiments of the present disclosure;

FIG. 30 illustrates a flowchart of a process for fabricating a light-shielding protection structure consistent with the disclosed embodiments of the present disclosure;

FIG. 31 illustrates a schematic diagram of the process illustrated in FIG. 30, consistent with the disclosed embodiments of the present disclosure;

FIG. 32 illustrates a flowchart of a method for manufacturing another display panel, consistent with the disclosed embodiments of the present disclosure;

FIG. 33 illustrates a schematic diagram of the method illustrated in FIG. 32, consistent with the disclosed embodiments of the present disclosure; and

FIG. 34 illustrates a schematic structural diagram of a display device consistent with the disclosed embodiments of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Technologies, methods, and equipment known to those of ordinary skill in relevant fields may not be discussed in detail, but where appropriate, these technologies, methods, and equipment should be regarded as part of the present disclosure.

It should be noted that in the present disclosure, relational terms such as “first” and “second” are only used to distinguish one entity or operation from another entity or operation, and do not necessarily require or imply that such actual relationship or sequence exists between these entities or operations. Terms “comprise”, “include” or any other variations thereof are intended to cover a non-exclusive inclusion. A process, method, article, or apparatus that includes a series of elements includes not only the series of elements, but also other elements not expressly listed, or elements inherent to such a process, method, article, or apparatus. Without further limitation, an element defined by a statement like “comprises a . . . ” does not exclude the presence of additional identical elements in a process, method, article, or apparatus that includes the foregoing element. In the present disclosure, that layer A and layer B are “disposed on a same layer” means that layer A and layer B are made of a same material and in a same process.

Reference will now be made in detail to embodiments of the present disclosure, which are illustrated in the accompanying drawings. Similar labels and letters designate similar items in the drawings. Once an item is defined in one drawing, the item may not be defined and discussed in subsequent drawings.

In existing technology, the process of fabricating the light-shielding material is generally performed after the light-emitting element is transferred to the driving substrate. Specifically, the light-emitting element is first transferred to the driving substrate, and then a whole layer of light-shielding layer is disposed on a surface of the driving substrate facing the light-emitting element. The light-shielding layer covers the light-emitting element and the metal wirings in the driving substrate. Afterwards, the whole layer of light-shielding layer is patterned. A part of the light-shielding layer, which covers the light-emitting surface of the light-emitting element, is removed. As a result, after patterning, the light-shielding layer only covers the metal wirings on the driving substrate. However, the inventors found that, in existing technology, when the light-shielding layer is patterned, the light-emitting surface of the light-emitting element may be damaged, thereby affecting the light-emitting function of the light-emitting component. In addition, the light-shielding material may remain on the light-emitting surface of the light-emitting element, thereby affecting the light-emitting efficiency of the light-emitting element. As such, display brightness may be decreased, and the display effect of the display device may be affected.

To address the above issues in existing technology, the present disclosure provides a display panel. The display panel includes a driving substrate and a light-emitting element disposed on one side of the driving substrate.

The light-emitting element includes a light-emitting element body and a protection structure. The protection structure contacts and covers the light-emitting surface of the light-emitting element body. The light-emitting surface includes a first light-emitting surface and/or a side light-emitting surface. The first light-emitting surface is a surface on a side of the light-emitting element body away from the driving substrate. The plane where the side light-emitting surface is located intersects with the plane where the first light-emitting surface is located. The protection structures of at least a portion of the light-emitting elements are independently disposed.

The protection structure may protect the light-emitting element body, and the problem of light-shielding material remaining on the first light-emitting surface of the light-emitting element body may be avoided. Accordingly, the light-emitting efficiency of the light-emitting components may be improved, and the display effect of the display panel may thus be improved. In addition, since the protection structures in at least a portion of the light-emitting elements are independently disposed, the protection structures may protect the corresponding light-emitting element bodies. As such, when etching the light-shielding material, damage to the light-emitting surfaces of the light-emitting element bodies may be reduced or even avoided. Accordingly, the light-emitting effect and light-emitting efficiency of the light-emitting element body may be improved.

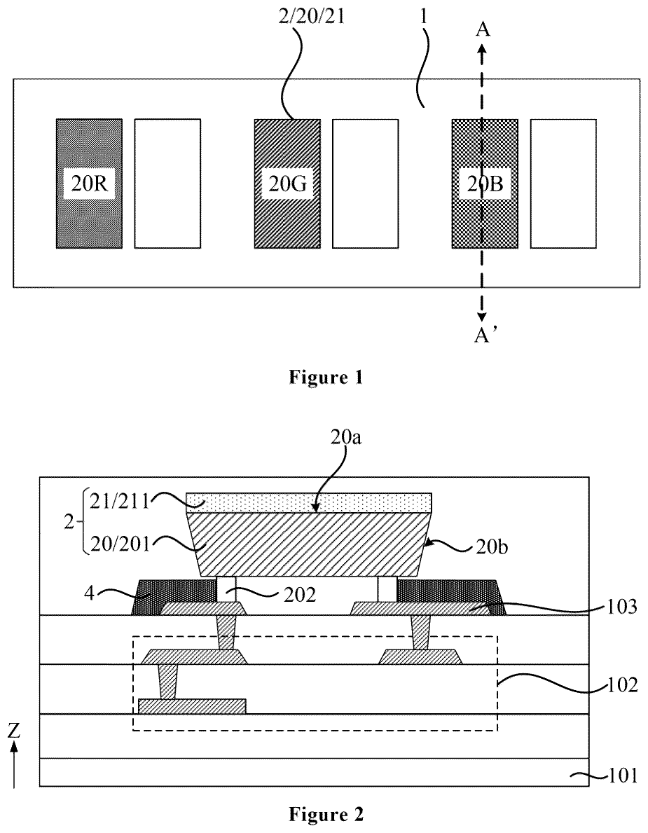

FIG. 1 illustrates a schematic structural diagram of a display panel consistent with the disclosed embodiments of the present disclosure. FIG. 2 illustrates a cross-sectional structural diagram along A-A′ in FIG. 1. Referring to FIGS. 1 and 2, in one embodiment, the display panel includes a driving substrate 1 and a light-emitting element 2 disposed on one side of the driving substrate 1. The light-emitting element 2 includes a light-emitting element body 20 and a protection structure 21. The protection structure 21 contacts and covers the light-emitting surface of the light-emitting element body 20. The light-emitting surface includes a first light-emitting surface 20a and/or a side light-emitting surface 20b. The first light-emitting surface 20a is a surface on a side of the light-emitting element body 20 away from the driving substrate 1. The plane where the light-emitting surface 20b is located intersects with the plane where the first light-emitting surface 20a is located. The protection structure 21 of at least a portion of the light-emitting elements 2 is independently disposed.

Referring to FIGS. 1 and 2, the driving substrate 1 may include a base substrate 101 and a driving layer disposed on one side of the base substrate. The base substrate 101 may be a rigid substrate or a flexible substrate, and the present disclosure does not limit a specific substrate. A specific structure of the driving layer may be set according to actual needs. Exemplarily, when the driving mode of the light-emitting element 2 is active driving, the driving layer may include a driving circuit 102 and a driving signal line 103. When the driving mode of the light-emitting element 2 is passive driving, the driving layer may include a driving signal line 103. The present disclosure does not elaborate on or limit a specific configuration of the driving layer.

The light-emitting element 2 may be a micro light-emitting element 2 such as a micro light-emitting diode (Micro LED) or a sub-millimeter light-emitting diode (Mini LED). The light-emitting element 2 is disposed on one side of the driving substrate 1. The light-emitting element body 20 may be a Micro LED chip. The light-emitting element body 20 may include a light-emitting layer 201 and an electrode 202. For Micro LED chips with different structures, relative positions of the light-emitting layer 201 and the electrode 202 may be different. In the configuration shown in FIG. 2, a flip chip is taken as an example. The light-emitting layer 201 may be located on a side of the electrode 202 away from the driving substrate 1, but the present disclosure is not limited thereto. In the present disclosure, the light-emitting element body 20 may also be a front-mounted chip (the electrode 202 is located on the side of the light-emitting layer 201 away from the driving substrate 1) or a vertical chip (the two electrodes are respectively located on two sides of the light-emitting layer 201 along the thickness direction of the display panel). The present disclosure does not elaborate on or limit a specific configuration of the light-emitting element body 20.

The light-emitting layer 201 is configured for emitting light. The electrode 202 is configured for electrically connecting to the driving layer in the driving substrate 1. The light-emitting surface of the light-emitting element body 20 may refer to the light-emitting surface of the light-emitting layer 201. The protection structure 21 contacts and covers at least a portion of the light-emitting surface of the light-emitting element body 20, thereby protecting at least a portion of the light-emitting surface of the light-emitting element body 20. In FIG. 1, the shape filled with a pattern represents the light-emitting element 2. The rectangular frame between adjacent light-emitting elements 2 represents a spare light-emitting element disposing area, which is configured to dispose a spare light-emitting element. The relative position relationship between the light-emitting element 2 and the spare light-emitting element disposing area shown in FIG. 1 is exemplary only, and the present disclosure is not limited thereto. In some other embodiments, the display panel may not be provided with the spare light-emitting element disposing area.

The first light-emitting surface 20a of the light-emitting element body 20 may refer to the light-emitting surface on a side of the light-emitting element body 20 away from the driving substrate 1. The side light-emitting surface 20b of the light-emitting element body 20 may refer to a connecting surface between the first light-emitting surface 20a and a surface on a side of the light-emitting element body 20 facing the driving side. The first light-emitting surface 20a and the side light-emitting surface 20b may be main light-emitting surfaces of the light-emitting element body 20.

The present disclosure does not limit a specific position of the protection structure 21 on the light-emitting surface. FIGS. 1 and 2 exemplarily show that the protection structure 21 may cover the first light-emitting surface 20a of the light-emitting element body 20, but the present disclosure is not limited thereto. In the configuration shown in FIGS. 1 and 2, a light-transmitting material may be used to fabricate the protection structure 21, forming a light-transmitting protection structure 211. In this way, even if a process of fabricating and patterning a light-shielding layer needs to be performed after the light-emitting element 2 is transported, the presence of the protection structure 21 may prevent the light-emitting element body 20 from being damaged. In addition, direct contact between the light-shielding material and the light-emitting element body 20 may be avoided. As such, the problem of the light-shielding material remaining on the first light-emitting surface 20a of the light-emitting element body 20 in existing technology may be avoided. Accordingly, the light-emitting efficiency of the light-emitting element 2 may be improved, and the display effect of the display panel may thus be improved.

In some other embodiments, when the protection structure 21 is disposed on the side light-emitting surface 20b of the light-emitting element body 20, the protection structure 21 may be directly fabricated by using the light-shielding material, forming a light-shielding protection structure. In this way, after the light-emitting element 2 is subsequently transported, no additional light-shielding layer needs to be fabricated. As such, the light-emitting efficiency of the light-emitting element body 20 may be improved, and the process of fabricating and patterning the light-shielding layer may be omitted. Accordingly, the fabrication process of the display panel may be simplified, and the problems of light-shielding material remaining on the first light-emitting surface 20a and the light-emitting element 2 being damaged may be avoided.

It should be noted that, in the present disclosure, the protection structures 21 of at least a portion of the light-emitting elements 2 are independently disposed. In other words, the protection structures 21 of at least a portion of the light-emitting elements 2 are independent of each other and do not contact each other. In some embodiments, the protection structures 21 of the light-emitting elements 2 each are independently disposed. The light-emitting element bodies 20 correspond to the protection structures 21 one by one, and any two of the adjacent protection structures 21 do not contact each other. In this way, the protection structure 21 may protect the corresponding light-emitting element body 20, and the protection effect may be improved.

The protection structure 21 may be fabricated on a portion of the light-emitting surface of the light-emitting element body 20 to form the light-emitting element 2 first, and then the light-emitting element 2 may be transferred to the driving substrate 1.

In the present disclosure, the light-emitting element includes a light-emitting element body and a protection structure. The protection structure contacts and covers the light-emitting surface of the light-emitting element body. The light-emitting surface includes a first light-emitting surface and/or a side light-emitting surface. The protection structure may protect the light-emitting element body, and the problem of light-shielding material remaining on the first light-emitting surface of the light-emitting element body may be avoided. As such, the light-emitting efficiency of the light-emitting component may be improved, and the display effect of the display panel may be improved. In addition, the protection structures of at least a portion of the light-emitting elements are independently disposed. The protection structure may protect the light-emitting element body corresponding to the protection structure. As such, when etching the light-shielding material, damage to the light-emitting surface of the light-emitting element may be reduced or even avoided. Accordingly, the light-emitting effect and light-emitting efficiency of the light-emitting element body may be improved.

In the present disclosure, the display panel may be a transparent display panel or a non-transparent display panel, and the present disclosure does not limit whether the display panel is transparent. For a non-transparent display panel, the light-shielding layer fabricated after transferring the light-emitting element to the driving substrate may be fabricated by an evaporation process, and the light-shielding material is likely to remain. With solutions provided by the present disclosure, the problem of residual light-shielding material may be avoided.

Optionally, still referring to FIGS. 1 and 2, in some embodiments, the protection structure 21 includes a light-transmitting protection structure 211. The light-transmitting protection structure 211 at least covers the first light-emitting surface 20a.

In one embodiment, the light-transmitting protection structure 211 may be made of a light-transmitting material. The light-transmitting protection structure 211 at least contacts and covers the first light-emitting surface 20a. The presence of the light-transmitting protection structure 211 may not affect the light emission of the first light-emitting surface 20a of the light-emitting element body 20. Accordingly, the light-emitting efficiency of the light-emitting element body 20 may not be affected.

When the protection structure 21 is a light-transmitting protection structure 211, a light-shielding layer may need to be disposed in a subsequent process. In this case, along the thickness direction Z of the display panel, the portion of the light-shielding layer overlapping the first light-emitting surface 20a is in contact with the protection structure 21 covered by the first light-emitting surface 20a. When this part of the light-shielding layer is removed, the first light-emitting surface 20a may not be damaged. In addition, compared with the first light-emitting surface 20a, the surface of the protection structure 21 is smoother. As such, the light-shielding material may not remain on the protection structure 21. Accordingly, the light-emitting efficiency of the first light-emitting surface 20a may be improved.

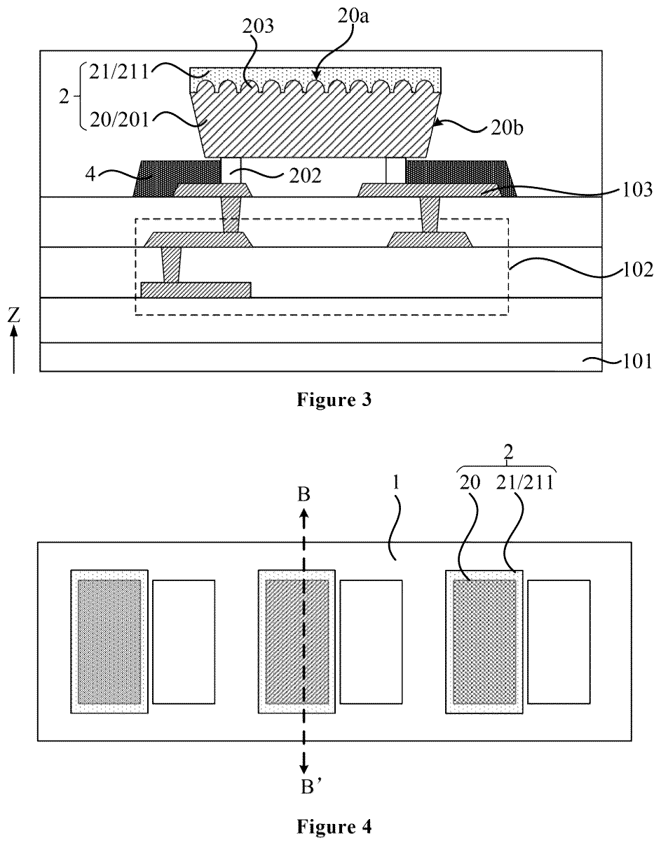

FIG. 3 illustrates a partial cross-sectional structural diagram of a display panel consistent with the disclosed embodiments of the present disclosure. The cross-sectional position is similar to the cross-sectional position shown in FIG. 2. Referring to FIG. 3, in one embodiment, the first light-emitting surface 20a includes a plurality of microstructures 203.

The plurality of microstructure 203 may refer to a plurality of protrusions and/or depressions on the first light-emitting surface 20a. As an example, in FIG. 3, the first light-emitting surface 20a includes a plurality of protruding microstructures 203, but the present disclosure is not limited thereto. Due to the presence of the microstructures 203, the first light-emitting surface 20a may be a rough surface. As such, the light-emitting angle of the light-emitting element body 20 may be adjusted by the microstructures 203. The light emitted from the light-emitting element body 20 may be prevented from being totally internally reflected at the first light-emitting surface 20a. Accordingly, the light-emitting efficiency of the light-emitting element body 20 may be improved.

When the first light-emitting surface 20a is disposed with a plurality of microstructures 203, the roughness of the first light-emitting surface 20a may be relatively large. When a process in existing technology is used, the light-shielding material may remain on the first light-emitting surface 20a. In the present disclosure, the first light-emitting surface 20a is covered with the light-transmitting protection structure 211. The light-transmitting protection structure 211 may improve the smoothness of the surface of the light-emitting element 2 facing away from the driving substrate 1. Accordingly, the difficulty of removing the light-shielding material on the surface of the light-emitting element 2 facing away from the driving substrate 1 may be reduced, and the problem of residual light-shielding material may be avoided.

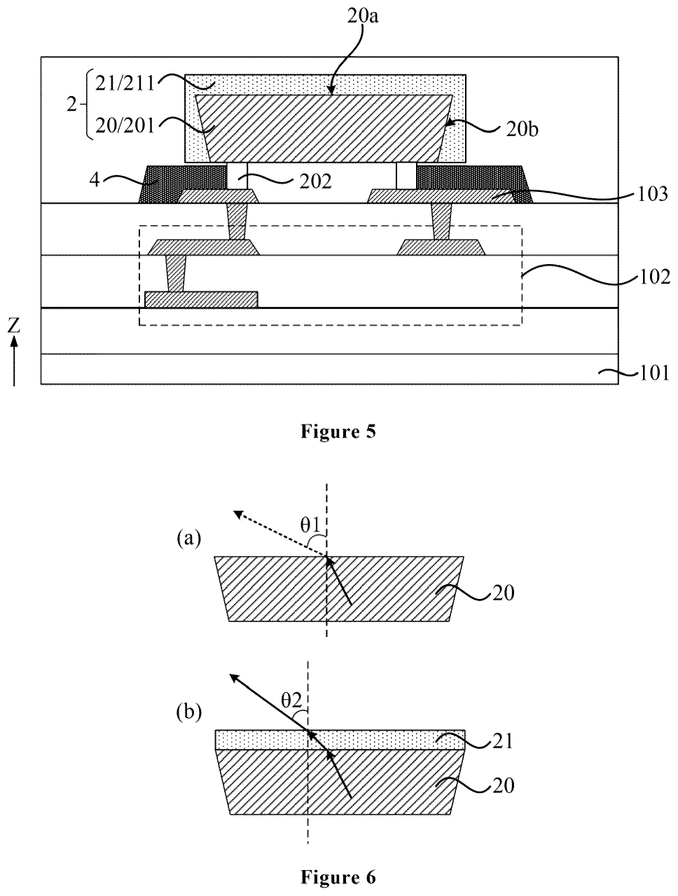

In the configuration shown in FIG. 1, the light-transmitting protection structure 211 only covers the first light-emitting surface 20a. FIG. 4 illustrates a schematic structural diagram of another display panel consistent with the disclosed embodiments of the present disclosure. FIG. 5 illustrates a cross-sectional structural diagram along B-B′ in FIG. 4. Referring to FIGS. 4 and 5, in one embodiment, the light-transmitting protection structure 211 covers the first light-emitting surface 20a and the side light-emitting surface 20b. The light-transmitting protection structure 211 may protect the first light-emitting surface 20a and the side light-emitting surface 20b simultaneously. In addition, when the light-transmitting protection structure 211 covers the side light-emitting surface 20b, the light emitted from the light-emitting surface 20b of the light-emitting element 2 may also be emitted through the light-transmitting protection structure 211. Accordingly, the light-emitting efficiency of the light-emitting element 2 may be improved, and the display effect in wide viewing angles may be improved.

Optionally, in one embodiment, the refractive index of the light-transmitting protection structure 211 may be smaller than the refractive index of the light-emitting element body 20.

Specifically, the light emitted from the light-emitting element body 20 may enter the light-transmitting protection structure 211 through the light-emitting element body 20. The refractive index of the light-transmitting protection structure 211 may be set to be smaller than the refractive index of the light-emitting element body 20. After passing through a medium with a smaller refractive index, the light may be emitted to the outside environment. As such, the probability of total reflection of light at the interface between the light-emitting element body 20 and the light-transmitting protection structure 211 may be reduced, and the light-emitting efficiency may be improved. In addition, the light to be emitted is more likely in a direction perpendicular or nearly perpendicular to the first light-emitting surface 20a. As such, the light-emitting angle may be adjusted, and the brightness of the light at a right viewing angle may be improved.

FIG. 6 illustrates a schematic diagram of light propagation consistent with the disclosed embodiments of the present disclosure. Arrows in FIG. 6 represent light rays. As shown in FIG. 6(a), when light is emitted directly from the light-emitting element body 20 to the air, since the refractive index difference between the air and the light-emitting element body 20 may be large, the refraction angle θ1 of the outgoing light may be large. As shown in FIG. 6(b), the light-transmitting protection structure 211 is disposed on the light-emitting surface of the light-emitting element body 20, and the refractive index of the light-transmitting protection structure 211 is set to be smaller than the refractive index of the light-emitting element body 20. The light-transmitting protection structure 211 is equivalent to a transition medium between the light-emitting element body 20 and the air. The difference in refractive index between two adjacent media in the light propagation path may be small. Accordingly, the refraction angle θ2 of the outgoing light may be reduced, and the light-emitting angle may thus be adjusted.

The present disclosure does not limit a specific value of the refractive index of the light-transmitting protection structure 211. Those skilled in the art may set the refractive index of the light-transmitting protection structure 211 according to actual needs.

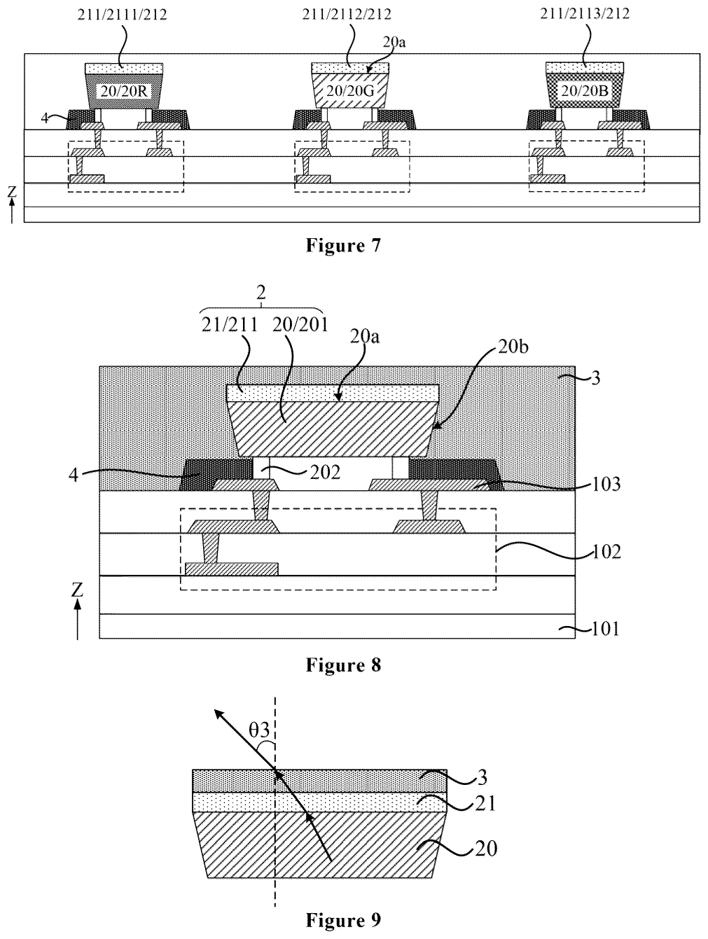

FIG. 7 illustrates a partial cross-sectional structural diagram of another display panel consistent with the disclosed embodiments of the present disclosure. Referring to FIGS. 1 and 7, the light-emitting element body 20 may include a first color light-emitting element body 20R, a second color light-emitting element body 20G, and a third color light-emitting element body 20B. The refractive index of the first color light-emitting element body 20R is greater than the refractive index of the second color light-emitting element body 20G and/or the third color light-emitting element body 20B. The light-transmitting protection structure 211 may include a first protection structure 2111, a second protection structure 2112 and a third protection structure 2113. The first protection structure 2111 contacts and covers the light-emitting surface of the first color light-emitting element body 20R. The second protection structure 2112 contacts and covers the light-emitting surface of the second color light-emitting element body 20G. The third protection structure 2113 contacts and covers the light-emitting surface of the third color light-emitting element body 20B. The refractive index of the first protection structure 2111 is greater than the refractive index of the second protection structure 2112 and/or the third protection structure 2113.

The first color light-emitting element body 20R, the second color light-emitting element body 20G and the third color light-emitting element body 20B are micro light-emitting diode chips of three different colors. The materials of the light-emitting layer 201 in the light-emitting element bodies 20 of different colors may be different. As such, the refractive indexes of the light-emitting element bodies 20 of different colors may be different. Accordingly, in the present disclosure, the light-transmitting protection structures 211 covering the light-emitting component bodies 20 of different colors may be differently set, based on the difference in refractive index of the light-emitting component bodies 20 of different colors. For example, the refractive index of the light-transmitting protection structure 211 over the light-emitting element body 20 with a larger refractive index may be larger, and the refractive index of the light-transmitting protection structure 211 over the light-emitting element body 20 with a smaller refractive index may also be smaller. As a result, the probability of total reflection of light of each color at the interface between the light-emitting element body 20 and the light-transmitting protection structure 211 may be low. In addition, the light-emitting viewing angle of the light-emitting element body 20 of each color may be adjusted, and thus the light-emitting brightness of the light-emitting element body 20 of each color at a right viewing angle may be improved.

Specifically, the light-transmitting protection structure 211 covering the first light-emitting surface 20a of the first-color light-emitting element body 20R may be defined as a first protection structure 2111. The light-transmitting protection structure 211 covering the first light-emitting surface 20a of the second-color light-emitting element body 20G may be defined as the second protection structure 2112. The light-transmitting protection structure 211 covering the first light-emitting surface 20a of the third-color light-emitting element body 20B may be defined as the third protection structure 2113. In one embodiment, among the light-emitting element bodies 20 of the three colors, the refractive index of the first color light-emitting element body 20R may be relatively large, and the refractive index of the second color light-emitting element body 20G and/or the refractive index of the third color light-emitting element body 20B may be relatively small. Accordingly, the refractive index of the first protection structure 2111 may be set to be greater than the refractive index of the second protection structure 2112 and/or the third protection structure 2113. As such, the refractive index difference between the light-emitting element body 20 of each color and the corresponding light-transmitting protection structure 211 may be balanced.

The first color light-emitting element body 20R may be a red light-emitting element body. The second color light-emitting element body 20G may be a green light-emitting element body. The third color light-emitting element body 20R may be a blue light-emitting element body. The combination of red, green and blue light-emitting element bodies may achieve full-color display. The inventors have found that, due to the element doping in the light-emitting layer of the red light-emitting element body, the refractive index of the light-emitting layer of the red light-emitting element body may be relatively large. Accordingly, the refractive index of the light-transmitting protection structure corresponding to the red light-emitting element body may be set to be relatively large, and the refractive index of the light-transmitting protection structure corresponding to the blue and/or green light-emitting element body may be set to be relatively small.

FIG. 8 illustrates a partial cross-sectional structural diagram of another display panel consistent with the disclosed embodiments of the present disclosure. Referring to FIG. 8, the display panel may also include an encapsulation layer 3 located on a side of the light-transmitting protection structure 211 away from the driving substrate 1. The refractive index of the light-transmitting protection structure 211 may be greater than the refractive index of the encapsulation layer 3.

Specifically, the encapsulation layer 3 is located on the light-emitting side of the light-emitting element 2. The encapsulation layer 3 may cover the light-transmitting protection structure 211 to achieve packaging and protection effects. The encapsulation layer 3 may be a whole-layer integrated structure. Along the thickness direction Z of the display panel, the encapsulation layer 3 may cover at least a portion of the light-emitting element 2. The encapsulation layers 3 corresponding to different light-emitting elements 2 may be in contact with each other and may be integrally arranged. The area between two adjacent light-emitting elements 2 may also be filled with the encapsulation layer 3. That is, the encapsulation layer 3 may cover at least a portion of the side light-emitting surface 20b of the light-emitting element body 20. Optionally, the encapsulation layer 3 located on the side of the first light-emitting surface 20a of the light-emitting element body 20 and the encapsulation layer 3 covering the side light-emitting surface 20b of the light-emitting element body 20 may be made of a same material and fabricated in a same process. Alternatively, the encapsulation layer 3 located on the side of the first light-emitting surface 20a of the light-emitting element body 20 and the encapsulation layer 3 covering the side light-emitting surface 20b of the light-emitting element body 20 may be made of different materials and may be fabricated in different processes.

In one embodiment, the refractive index of the encapsulation layer 3 may be set to be smaller than the refractive index of the light-transmitting protection structure 211. As such, the probability of total reflection of the light emitted from the light-emitting element body 20 at the interface between the light-transmitting protection structure 211 and the encapsulation layer 3 may be reduced, and the light-emitting efficiency may be improved.

FIG. 9 illustrates another schematic diagram of light propagation consistent with the disclosed embodiments of the present disclosure. Referring to FIG. 9, by setting the refractive index of the encapsulation layer 3 to be smaller than the refractive index of the light-transmitting protection structure 211, the encapsulation layer 3 may serve as a transition medium between the light-transmitting protection structure 211 and the air. As such, the refractive index difference between two adjacent media in the light propagation path may be reduced, and the refraction angle θ3 of the light emitted from the encapsulation layer 3 may be reduced. Accordingly, the brightness of the light emitted at a right viewing angle may be improved. The present disclosure does not limit a specific value of the refractive index of the encapsulation layer 3. Those skilled in the art may set the refractive index of the encapsulation layer 3 according to actual needs.

Optionally, in one embodiment, the display panel may also include an encapsulation layer 3 located on a side of the light-transmitting protection structure 211 away from the driving substrate 1. The light-transmitting protection structure 211 and the encapsulation layer 3 may be made of different materials.

The location of the encapsulation layer 3 will not be elaborated here, and reference may be made to FIG. 8. In one embodiment, the light-transmitting protection structure 211 and the encapsulation layer 3 may be made of different materials in different fabrication processes. Those skilled in the art may select materials with different refractive indices and/or different hardnesses to fabricate the light-transmitting protection structure 211 and the encapsulation layer 3 according to actual needs.

For example, a glue material with a large refractive index and a small hardness may be used to fabricate the light-transmitting protection structure 211. A glue material with small refractive index and high hardness may be used to fabricate the encapsulation layer 3. As such, the light-emitting efficiency at a right viewing angle and the packaging effect may be improved, and the light-transmitting protection structure 211 may be prevented from damaging the light-emitting element body 20.

In some embodiments, the light-transmitting protection structure 211 may be made of a material including polydimethylsiloxane (PDMS). The encapsulation layer 3 may be made of silicone potting glue. The present disclosure is not limited thereto.

Optionally, the side of the encapsulation layer 3 facing away from the driving substrate 1 may also include an encapsulation cover plate (not shown in FIGS. 8 and 9). The packaging cover plate may be a glass cover plate, protecting the entire display panel.

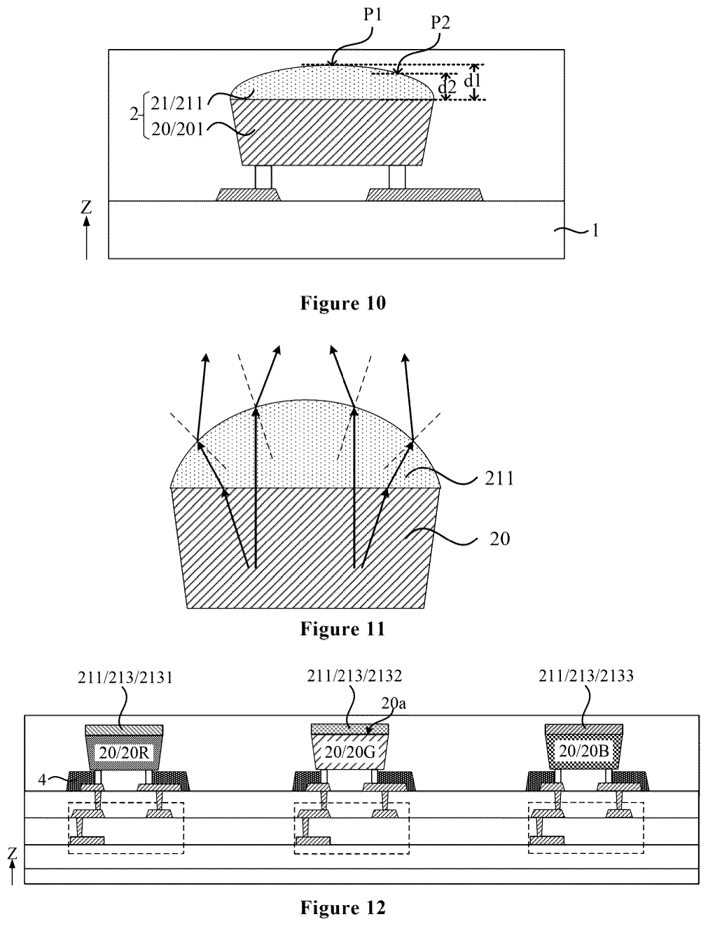

FIG. 10 illustrates a schematic structural diagram of a light-emitting element consistent with the disclosed embodiments of the present disclosure. Referring to FIG. 10, in one embodiment, the light-transmitting protection structure may include a first position P1 and a second position P2. Along the thickness direction Z of the display panel, the thickness of the light-transmitting protection structure 211 at the first position P1 may not be equal to the thickness of the light-transmitting protection structure 211 at the second position P2.

Specifically, in one embodiment, the thicknesses at different positions of a same light-transmitting protection structure 211 may be different. The light-emitting surface of the light-transmitting protection structure 211 may not be a flat surface extending in a certain direction, but a surface with ups and downs. As shown in FIG. 10, the surface of the light-transmitting protection structure 211 away from the light-emitting element body 20 may include at least a first position P1 and a second position P2. The thickness of the light-transmitting protection structure 211 at the first position P1 and the thickness of the light-transmitting protection structure 211 at the second position P2 may be different, such that the heights of the light-emitting surface of the light-transmitting protection structure 211 may be different. For example, as shown in FIG. 10, the thickness d1 of the light-transmitting protection structure 211 at the first position P1 may be greater than the thickness d2 of the light-transmitting protection structure 211 at the second position P2. As such, the height of the light-emitting surface of the light-transmitting protection structure 211 at the first position P1 is greater than the height of the light-emitting surface at the second position P2. The present disclosure is not limited thereto.

The first position P1 and the second position P2 shown in FIG. 10 are examples only. Any two positions on the light-transmitting protection structure 211 corresponding to different thicknesses may be regarded as the first position P1 and the second position P2. Light-emitting surface with different shapes may have different modulation effects on the light emitted by the light-emitting element body 20. In this way, the shape of the light-emitting surface of the light-transmitting protection structure 211 may be designed according to actual conditions. Accordingly, the light-emitting angle may be adjusted according to the needs to meet diverse design requirements of the light-emitting angle.

In addition, in a subsequent process of light-shielding layer preparation and patterning, if the light-shielding material remains on the light-transmitting protection structure 211, removing the residual light-shielding material may also cause the light-emitting surface of the light-transmitting protection structure 211 to have ups and downs.

Optionally, as shown in FIG. 10, the surface of the light-transmitting protection structure 211 close to the light-emitting element body 20 is parallel or approximately parallel to the plane where the driving substrate 1 is located. The surface of the light-transmitting protection structure 211 away from the light-emitting element body 20 may have ups and downs.

In addition, with continued reference to FIG. 10, in one embodiment, the light-emitting surface of the light-transmitting protection structure 211 may be set to be convex toward the side away from the driving substrate 1.

As shown in FIG. 10, in one embodiment, the light-emitting surface of the light-transmitting protection structure 211 may be set as a convex lens structure. That is, along the thickness direction Z of the display panel, the spacing between the central area of the light-emitting surface of the light-transmitting protection structure 211 and the light-emitting element body 20 may be greater than the spacing between the edge area of the light-emitting surface of the light-transmitting protection structure 211 and the light-emitting element body 20. FIG. 11 illustrates another schematic diagram of light propagation consistent with the disclosed embodiments of the present disclosure. Arrows in FIG. 11 represent light rays. Referring to FIG. 11, when the light-emitting surface of the light-transmitting protection structure 211 is convex toward the side away from the driving substrate 1, the light-emitting surface of the light-transmitting protection structure 211 may be a convex surface, and light may be focused. Light emitted from the light-emitting element body 20 may propagate toward the central area of the light-transmitting protection structure 211. Accordingly, brightness of the light emitted at a right viewing angle may be improved.

FIG. 12 illustrates a partial cross-sectional structural diagram of another display panel consistent with the disclosed embodiments of the present disclosure. Referring to FIGS. 7 and 12, the light-transmitting protection structure 211 may include a transparent protection structure 212, or the light-transmitting protection structure 211 may include a color-filtering protection structure 213.

Referring to FIG. 7, in some embodiments, a transparent colloid material may be used to fabricate a light-transmitting protection structure 211 to form a transparent protection structure 212. The transparent protection structure 212 may allow light of various colors to pass through. In this configuration, the transparent protection structures 212 covering the first light-emitting surfaces 20a of the light-emitting elements 2 of different colors may be made of a same material. The difficulty of fabricating the transparent protection structure 212 may be reduced.

Referring to FIG. 12, in some other embodiments, a color-resisting material may be used to fabricate the light-transmitting protection structure 211 to form a color-filtering protection structure 213. The color-filtering protection structure 213 may allow light of a corresponding color to pass through. When the light-emitting element body 20 includes a first color light-emitting element body 20R, a second color light-emitting element body 20G and a third color light-emitting element body 20B, the color-filtering protection structure 213 may include a first color-filtering protection structure 2131, a second color-filtering protection structure 2132 and a third color-filtering protection structure 2133. The first color-filtering protection structure 2131 contacts and covers the first light-emitting surface 20a of the first color light-emitting element body 20R. The second color-filtering protection structure 2132 contacts and covers the first light-emitting surface 20a of the second color light-emitting element body 20G. The third color-filtering protection structure 2133 contacts and covers the first light-emitting surface 20a of the third color light-emitting element body 20B.

The first color-filtering protection structure 2131 is made of a color-resisting material of the first color, and is configured to transmit the first color light and filter out the second color and the third color light. The second color-filtering protection structure 2132 is made of a color-resisting material of the second color, and is configured to transmit the second color light and filter out the first color and the third color light. The third color-filtering protection structure 2133 is made of a color-resisting material of the third color, and is configured to transmit the third color light, and filter out the first color and the second color light.

By setting the light-transmitting protection structure 211 as the color-filtering protection structure 213, color purity of the light emitted by the light-emitting element 2 may be improved, and the problem of color deviation may be avoided.

Optionally, still referring to FIG. 2, the driving substrate 1 may include a driving circuit 102 and a driving signal line 103. The driving circuit 102 is electrically connected to the driving signal line 103 and the light-emitting element 2 respectively. The display panel may also include a first light-shielding structure 4. The first light-shielding structure 4 may cover the driving circuit 102 and the driving signal line 103. The first light-shielding structure 4 may expose the side light-emitting surface 20b, or the first light-shielding structure 4 may cover at least a portion of the side light-emitting surface 20b.

Specifically, the driving circuit 102 may include structures such as transistors and capacitors. The electrode 202 of the light-emitting element body 20 may be electrically connected to the driving circuit 102 and the driving signal line 103, to transmit the driving signal to the light-emitting element 2. The present disclosure does not elaborate or limit a specific arrangement of the driving circuit 102 and the driving signal line 103, and those skilled in the art may arrange the driving circuit 102 and the driving signal line 103 according to actual needs.

As shown in FIG. 2, the first light-shielding structure 4 is the light-shielding layer mentioned above. Along the thickness direction Z of the display panel, the first light-shielding structure 4 may overlap with the driving circuit 102 and the driving signal line 103, and light reflection by the driving circuit 102 and the driving signal line 103 may be avoided. Along the thickness direction Z of the display panel, the first light-shielding structure 4 at most partially contacts and covers the light-transmitting protection structure 211. As such, the first light-shielding structure 4 may be prevented from affecting the light emission of the light-emitting element body 20.

The first light-shielding structure 4 may be fabricated after the light-emitting element 2 is transferred to the driving substrate 1. Specifically, a whole layer of a first initial light-shielding layer may be deposited on a side of the driving substrate 1 facing the light-emitting element 2. Then, the first initial light-shielding layer may be patterned to form the first light-shielding structure 4 covering the driving circuit 102 and the driving signal line 103. The presence of the light-transmitting protection structure 211 may prevent the first initial light-shielding layer from remaining on the first light-emitting surface 20a of the light-emitting element body 20.

As shown in FIG. 2, in one embodiment, the first light-shielding structure 4 exposes the side light-emitting surface 20b. In this configuration, the side light-emitting surface 20b of the light-emitting element 2 has a light-emitting path, and the light-emitting efficiency of the light-emitting element 2 may be improved. In addition, the first shading structure 4 may also shield the bottom of the light-emitting element 2 (the area where the electrode 202 is located) to a certain extent, thereby reducing the reflectivity of the display panel.

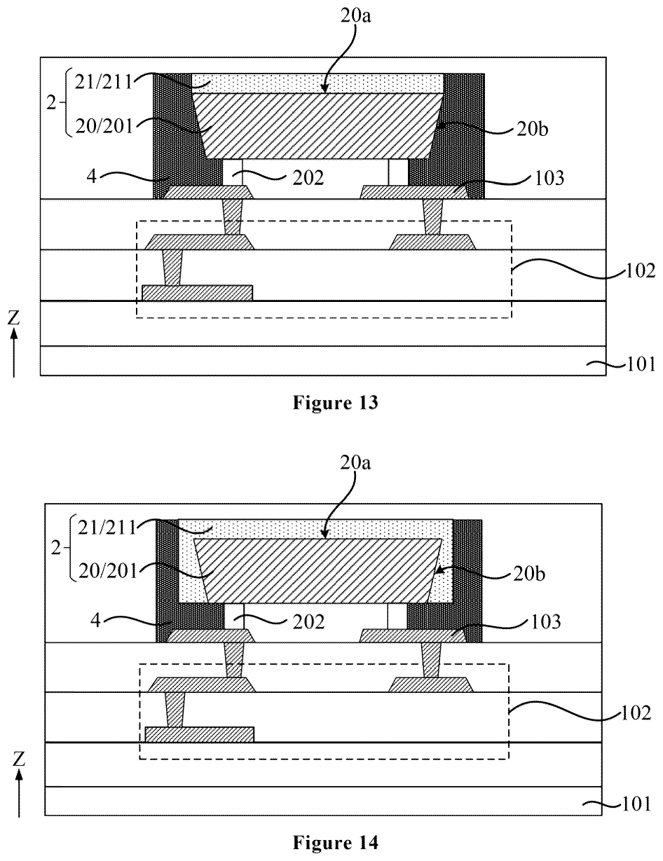

FIG. 13 illustrates a partial cross-sectional structural diagram of another display panel consistent with the disclosed embodiments of the present disclosure. FIG. 14 illustrates a partial cross-sectional structural diagram of another display panel consistent with the disclosed embodiments of the present disclosure. As shown in FIG. 13, in one embodiment, the first light-shielding structure 4 may entirely cover the side light-emitting surface 20b of the light-emitting element 2. The first light-shielding structure 4 may block the side light of the light-emitting element 2, such that the light is emitted from the first light-emitting surface 20a. Accordingly, the problem of large visual angle deviation caused by side light may be eased. As shown in FIG. 14, in one embodiment, the light-transmitting protection structure 211 covers the first light-emitting surface 20a and the side light-emitting surface 20b of the light-emitting element body 20. The first light-shielding structure 4 covers the side of the light-transmitting protection structure 211 away from the side light-emitting surface 20b. In this way, the light-emitting efficiency of the light-emitting element 2 and the problem of large viewing angle color shift may each be taken into consideration.

Referring to FIGS. 13 and 14, in some embodiments, the light-transmitting protection structure 211 may be a transparent protection structure 212. In some other embodiments, the transparent protection structure 212 may be a color-filtering protection structure 213.

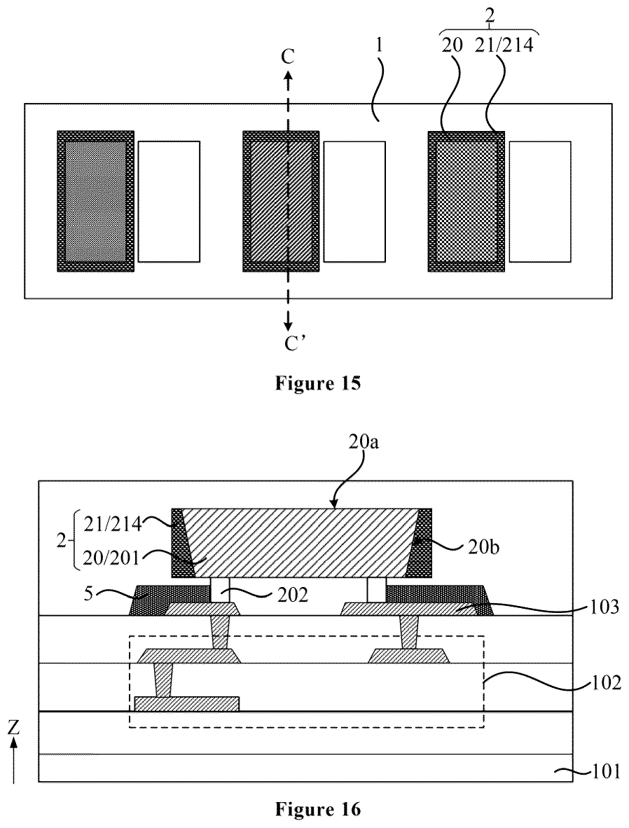

FIG. 15 illustrates a schematic structural diagram of another display panel consistent with the disclosed embodiments of the present disclosure. FIG. 16 illustrates a cross-sectional structural diagram along C-C′ in FIG. 15. Referring to FIGS. 15 and 16, in one embodiment, the protection structure 21 includes a light-shielding protection structure 214, and the light-shielding protection structure 214 covers the side light-emitting surface 20b.

As shown in FIGS. 15 and 16, the protection structure 21 may include the light-shielding protection structure 214 made of a light-shielding material. The light-shielding protection structure 214 covers at least a portion of the side light-emitting surface 20b of the light-emitting element body 20. The light-shielding protection structure 214 may reduce the reflection of light at the light-emitting element 2 and reduce the reflectivity of the light-emitting element 2. In addition, since the first light-emitting surface 20a is not covered by the light light-shielding protection structure 214, the light-emitting efficiency of the light-emitting element 2 may not be affected.

The light-shielding protection structure 214 may be disposed on the side light-emitting surface 20b of the light-emitting element body 20 before the light-emitting element 2 is transferred to the driving substrate 1. After the light-emitting element 2 is subsequently transferred, no additional light-shielding layer is required. Accordingly, the process may be simplified, and problems of light-shielding material remaining on the first light-emitting surface 20a and the light-emitting element 2 being damaged may be avoided.

The light-shielding protection structure 214 may be made of a black light-shielding material. The present disclosure does not limit a specific light-shielding material, and those skilled in the art may select the light-shielding material according to actual needs.

Further, still referring to FIGS. 15 and 16, the driving substrate 1 may include a driving circuit 102 and a driving signal line 103. The driving circuit 102 is electrically connected to the driving signal line 103 and the light-emitting element 2 respectively. The display panel may also include a second light-shielding structure 5. The second light-shielding structure 5 covers the driving circuit 102 and the driving signal line 103. The light-shielding protection structure 214 and the second light-shielding structure 5 may be independently disposed. The configuration of the driving circuit 102 and the driving signal line 103 is not elaborated here, and reference may be made to above descriptions.

The second light-shielding structure 5 is configured to shield the driving circuit 102 and the driving signal line 103, and light reflection by the driving circuit 102 and the driving signal line 103 may be avoided. A pixel area may include a light-emitting element 2, and a corresponding driving circuit 102 electrically connected to the light-emitting element. In the thickness direction Z of the display panel, the second light-shielding structure 5 may cover the edge of the pixel area. In the thickness direction Z of the display panel, the second light-shielding structure 5 may also overlap with the light-shielding protection structure 214. For example, when the projection area of the light-emitting element 2 on the driving substrate 1 is smaller than the projection area of the driving circuit 102, in the projection pattern on the driving substrate 1, the edge of the second light-shielding structure 5 may be located at the periphery of the light-shielding protection structure 214. In other words, the edge of the second light-shielding structure 5 may surround the light-shielding protection structure 214. The light-shielding protection structure 214 and the second light-shielding structure 5 may together play a light-shielding role. Accordingly, the reflectivity may be reduced, and the light-emitting efficiency of the light-emitting element 2 may be improved.

It should be noted that the light-shielding protection structure 214 and the second light-shielding structure 5 are independent structures fabricated in different processes. That is, the light-shielding protection structure 214 and the second light-shielding structure 5 do not contact each other and are independent of each other. Accordingly, the light-shielding protection structure 214 and the second shading structure 5 each may have a degree of freedom, and may be flexible in position arrangement.

Optionally, the light-shielding protection structure 214 and the second light-shielding structure 5 may be made of a same light-shielding material, or different light-shielding materials. The present disclosure does not limit whether the light-shielding protection structure 214 and the second light-shielding structure 5 are made of a same light-shielding material. In one embodiment, the light-shielding protection structure 214 may be made of a carbon black system material, for example, carbon black plus acrylic resin material. The second light-shielding structure 5 may be made of organic dye-based materials. The present disclosure is not limited thereto.

In one embodiment, the second light-shielding structure 5 may be disposed on one side of the driving substrate 1 first, and then the light-emitting element 2 may be transferred to the driving substrate 1. After the light-emitting element 2 is transferred to the driving substrate 1, no other light-shielding layer needs to be disposed.

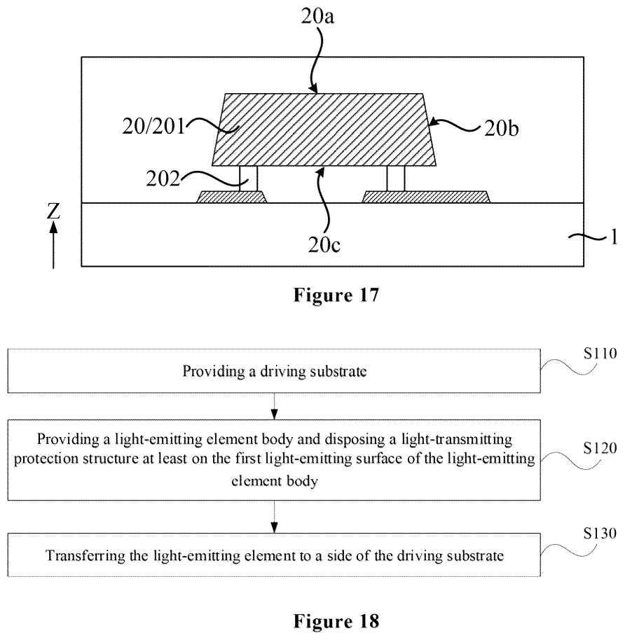

FIG. 17 illustrates a schematic structural diagram of another light-emitting element consistent with the disclosed embodiments of the present disclosure. With reference to FIGS. 2 and 17, in one embodiment, the light-emitting surface also includes a second light-emitting surface 20c. The second light-emitting surface 20c is located on a side of the first light-emitting surface 20a close to the driving substrate 1. Along the thickness direction Z of the display panel, the first light-emitting surface 20a covers the second light-emitting surface 20c, or the second light-emitting surface 20c covers the first light-emitting surface 20a.

The second light-emitting surface 20c is a surface disposed opposite to the first light-emitting surface 20a. The second light-emitting surface 20c faces the driving substrate 1. The electrode 202 of the light-emitting element body 20 may be disposed on the second light-emitting surface 20c. The side light-emitting surface 20b of the light-emitting element 2 may be the connecting surface of the first light-emitting surface 20a and the second light-emitting surface 20c. In the configuration shown in FIG. 2, along the thickness direction Z of the display panel, the first light-emitting surface 20a covers the second light-emitting surface 20c. That is, the projection area of the first light-emitting surface 20a in the thickness direction Z is larger than the projection area of the second light-emitting surface 20c in the thickness direction Z. The light-emitting element body 20 is in an inverted trapezoidal shape. The first light-emitting surface 20a has a larger area, and the light-emitting efficiency at a right viewing angle may be improved.

In the configuration shown in FIG. 17, along the thickness direction Z of the display panel, the second light-emitting surface 20c covers the first light-emitting surface 20a. That is, the projection area of the first light-emitting surface 20a in the thickness direction Z is smaller than the projection area of the second light-emitting surface 20c in the thickness direction Z. The light-emitting element body 20 is a regular trapezoidal eave structure. In this configuration, the light emitted from the side light-emitting surface 20b may also propagate upward. Accordingly, the light-emitting efficiency may be improved.

The present disclosure does not limit a specific shape of the light-emitting element body 20. FIGS. 2 and 17 only illustrate two optional shapes of the light-emitting element body 20.

In the present disclosure, the display panel may also include structures known to those skilled in the art, which will not be elaborated or limited in the present disclosure.

The present disclosure also provides a method for manufacturing a display panel. The method may be used to manufacture the display panel provided by the present disclosure. The method may include: Process 1, providing a driving substrate; and Process 2: transferring a light-emitting element to a side of the driving substrate. The light-emitting element includes a light-emitting element body and a protection structure. The protection structure contacts and covers the light-emitting surface of the light-emitting element body. The light-emitting surface includes a first light-emitting surface and/or a side light-emitting surface. The first light-emitting surface is a surface on a side of the light-emitting element body away from the driving substrate. The plane where the side light-emitting surface is located intersects with the plane where the first light-emitting surface is located. The protection structures in at least a portion of the light-emitting elements are independently arranged.

For structures of the driving substrate and the light-emitting element, reference may be made to the above embodiments and corresponding drawings, which will not be elaborated here. In the method for manufacturing a display panel provided by the present disclosure, a protection structure is set in a light-emitting element. The protection structure may protect the light-emitting element body. Accordingly, the problem of the light-shielding layer material remaining on the first light-emitting surface of the light-emitting element body may be avoided, the light-emitting efficiency of the light-emitting element may be improved, and the display effect may be improved. In addition, the protection structures in at least a portion of the light-emitting elements are independently arranged. The protection structures may protect the corresponding light-emitting element bodies and improve the protection effect.

Optionally, in some embodiments, the protection structure may be a light-transmitting protection structure. In one embodiment, before Process 2, the method may also include: providing a light-emitting element body and disposing a light-transmitting protection structure at least on the first light-emitting surface of the light-emitting element body.

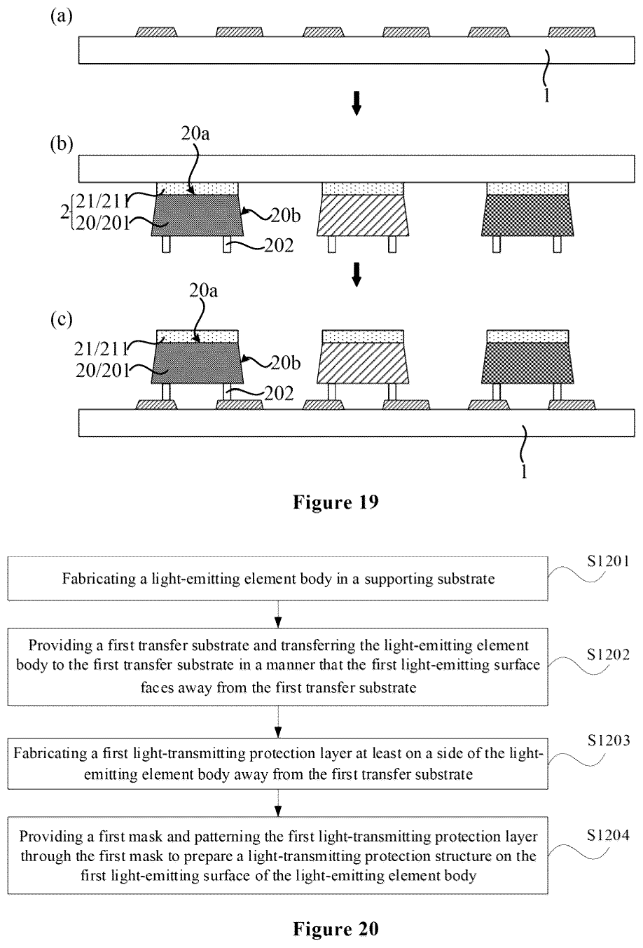

FIG. 18 illustrates a flowchart of a method for manufacturing a display panel consistent with the disclosed embodiments of the present disclosure. FIG. 19 illustrates a schematic diagram of the method illustrated in FIG. 18. Referring to FIGS. 18 and 19, the method specifically includes S110, S120 and S130.

S110, providing a driving substrate.

S120, providing a light-emitting element body and disposing a light-transmitting protection structure at least on the first light-emitting surface of the light-emitting element body. The light-emitting element body may refer to a micro light-emitting diode chip. The light-emitting element body 20 may include a light-emitting layer 201 and an electrode 202. The light-emitting layer 201 may be disposed on a side of the electrode 202 away from the driving substrate 1. The light-emitting layer 201 is configured for emitting light, and the electrode 202 is configured for connecting with conductive structures in the driving substrate 1.

Referring to FIG. 19(b), the light-transmitting protection structure 211 may be disposed at least on the first light-emitting surface 20a of the light-emitting element body 20. The light-transmitting protection structure 211 is made of a light-transmitting material. The light-transmitting protection structure 211 may be disposed in one-to-one correspondence with the light-emitting element 2.

S130, transferring the light-emitting element to a side of the driving substrate. The transfer process of light-emitting element 2 transfer may be a mass transfer process. For specific details of the transfer process, reference may be made to existing technology. The present disclosure does not elaborate on or limit specific details of the transfer process.

In one embodiment, before transferring the light-emitting element to the driving substrate, a light-transmitting protection structure may be disposed on the light-emitting element body. The light-transmitting protection structure may protect the first light-emitting surface, and damage to the first light-emitting surface during the transferring process may be avoided. Even when a process of the light-shielding layer deposition and patterning is required after the light-emitting element is transferred, presence of the light-transmitting protection structure may prevent the light-shielding material from directly contacting the light-emitting element body. Accordingly, the problem of light-shielding material remaining on the first light-emitting surface of the light-emitting element body in existing technology may be avoided, and the light-emitting efficiency of the light-emitting element may be improved.

The specific process of fabricating the light-transmitting protection structure is not limited in the present disclosure. Examples of the process for fabricating light-transmitting protection structures are described below.

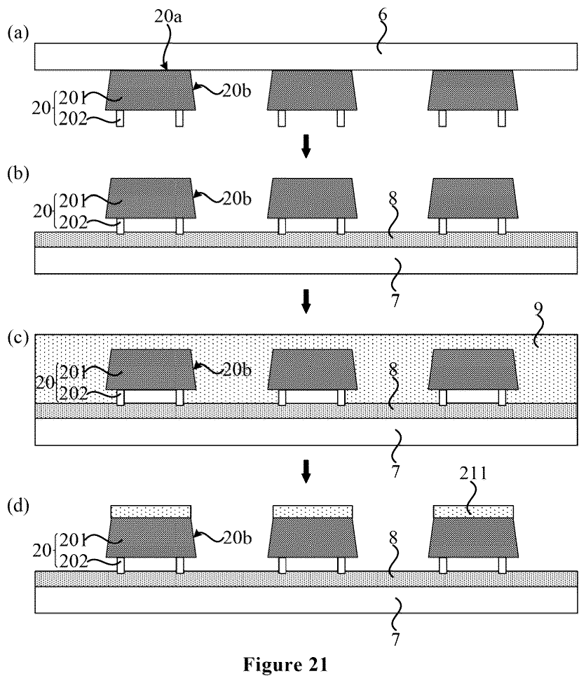

FIG. 20 illustrates a flowchart of a process for fabricating a light-transmitting protection structure, consistent with the disclosed embodiments of the present disclosure. FIG. 21 illustrates a schematic diagram of the process illustrated in FIG. 20. Referring to FIGS. 20 and 21, S120 may include S1201, S1202, S1203 and S1204.

S1201, fabricating a light-emitting element body in a supporting substrate.

Referring to FIG. 21(a), the supporting substrate 6 may be a silicon chip or wafer. The supporting substrate 6 may be used as a growth base for the light-emitting element body 20. A plurality of light-emitting element bodies 20 may be fabricated on the supporting substrate 6. The light-emitting layer 201 of the light-emitting element body 20 is close to the supporting substrate 6. The electrode 202 is located on the side of the light-emitting layer 201 away from the supporting substrate 6. That is, the first light-emitting surface 20a of the light-emitting element body 20 faces the supporting substrate 6. The process for fabricating the light-emitting element body 20 is not limited in the present disclosure, and those skilled in the art may determine the process according to actual needs.

S1202, providing a first transfer substrate and transferring the light-emitting element body to the first transfer substrate in a manner that the first light-emitting surface faces away from the first transfer substrate.

Referring to FIG. 21(b), a first transfer substrate 7 is provided, and a first release adhesive layer 8 may be disposed on one side of the first transfer substrate 7. After aligning the supporting substrate 6 with the first transfer substrate 7, the light-emitting element body 20 on the supporting substrate 6 is transferred to the first transfer substrate 7. The electrode 202 of the light-emitting element body 20 is fixed to a first release adhesive layer 8.

The plurality of light-emitting element bodies 20 on the supporting substrate 6 may be light-emitting element bodies 20 of a same color. In S1202, the light emitting element bodies 20 transferred to the first transfer substrate 7 may be of a same color. The process of transferring the light-emitting device body 20 from the supporting substrate 6 to the first transfer substrate 7 may be defined as a first transfer process.

S1203, fabricating a first light-transmitting protection layer at least on a side of the light-emitting element body away from the first transfer substrate.

Referring to FIG. 21(c), an entire layer of a first light-transmitting protection layer 9 may be prepared by a coating process. The first light-transmitting protection layer 9 may cover the light-emitting element bodies 20 and the first release adhesive layers 8 exposed between adjacent light-emitting element bodies 20. The first light-transmitting protection layer 9 may be made of a resin material with high light transmittance, such as PDMS, but the present disclosure is not limited thereto.

S1204, providing a first mask, and patterning the first light-transmitting protection layer through the first mask to prepare a light-transmitting protection structure on the first light-emitting surface of the light-emitting element body.

The pattern design of the first mask matches the arrangement of the light-emitting element bodies 20 on the first transfer substrate 7. Referring to FIG. 21(d), the first light-transmitting protection layer 9 is patterned using the first mask, to remove the first light-transmitting protection layer 9 in the area of the first release adhesive layer 8 where the light-emitting element body 20 is not disposed. The first light-transmitting protection layer 9 on the first light-emitting surface 20a of the light-emitting element body 20 is retained. The retained portion of the first light-transmitting protection layer 9 forms a light-transmitting protection structure 211. The patterning process may be a photolithography plus etching process, which is not elaborated or limited in the present disclosure.

After S1204, other transfer processes may also be included. In a subsequent transfer process, the light-transmitting protection structure 211 may play a protection role to prevent the light-emitting element body 20 from being damaged.

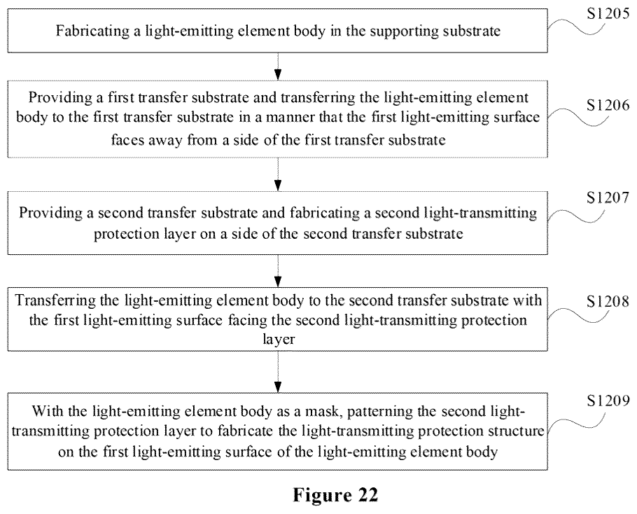

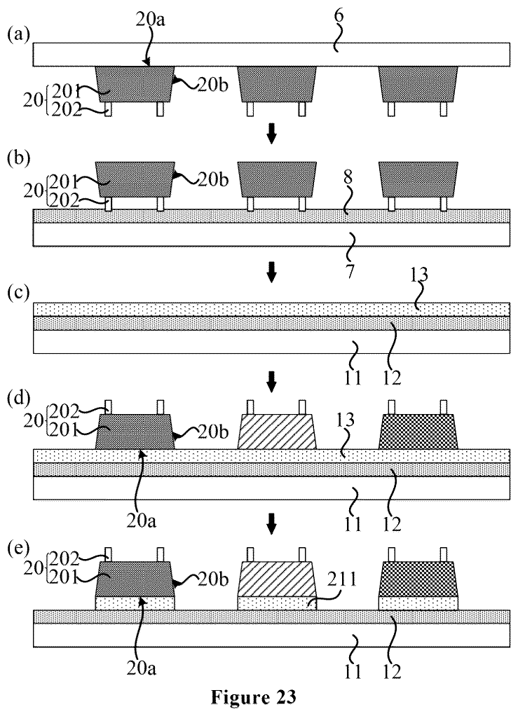

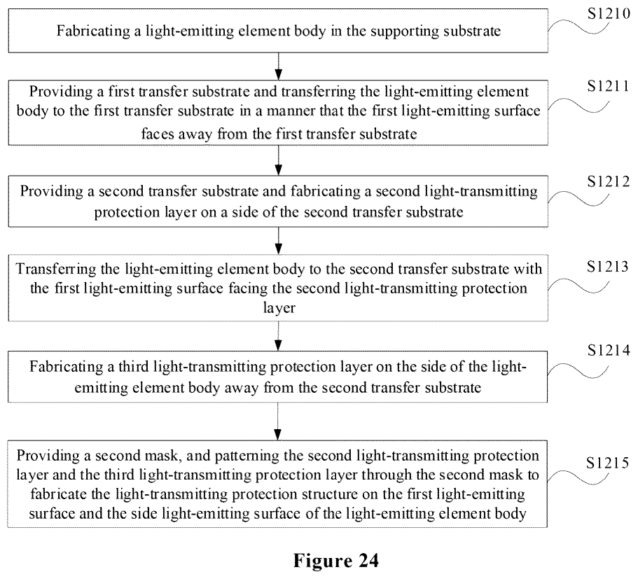

FIG. 22 illustrates a flowchart of a process for fabricating another light-transmitting protection structure, consistent with the disclosed embodiments of the present disclosure. FIG. 23 illustrates a schematic diagram of the process illustrated in FIG. 22. With reference to FIGS. 22 and 23, S120 may include S1205, S1206, S1207, S1208, and S1209.

S1205, fabricating a light-emitting element body in the supporting substrate.

S1206, providing a first transfer substrate and transferring the light-emitting element body to the first transfer substrate in a manner that the first light-emitting surface faces away from a side of the first transfer substrate.

For implementation of S1205 and S1206, reference may be made to S1201 and S1202, which will not be elaborated here.

S1207, providing a second transfer substrate and fabricating a second light-transmitting protection layer on a side of the second transfer substrate.

Referring to FIG. 23(c), a second transfer substrate 11 is provided. A second release adhesive layer 12 may be disposed on a side of the second transfer substrate 11. A whole layer of a second light-transmitting protection layer 13 may be coated on one side of the second release adhesive layer 12 by a coating process. The second light-transmitting protection layer 13 and the first light-transmitting protection layer 9 may be made of a same material.

S1208, transferring the light-emitting element body to the second transfer substrate with the first light-emitting surface facing the second light-transmitting protection layer.

Referring to FIG. 23(d), after aligning the first transfer substrate 7 with the second transfer substrate 11, the light-emitting element body 20 on the first transfer substrate 7 may be transferred to the second transfer substrate 11. The first light-emitting surface 20a of the light-emitting element body 20 is fixed to the second light-transmitting protection layer 13. The process of transferring the light-emitting element body 20 from the first transfer substrate 7 to the second transfer substrate 11 may be defined as a second transfer process. In the second transfer process, the light-emitting element bodies 20 of different colors may be transferred to a same second transfer substrate 11 to achieve the transfer integration of light-emitting elements 2 of different colors.

S1209, with the light-emitting element body as a mask, patterning the second light-transmitting protection layer to fabricate the light-transmitting protection structure on the first light-emitting surface of the light-emitting element body.

Referring to FIG. 23(e), in one embodiment, along the thickness direction Z of the second transfer substrate 11, the second light-transmitting protection layer 13 is located between the light-emitting element body 20 and the second transfer substrate 11. The first light-emitting surface 20a faces the second light-transmitting protection layer 13. In this configuration, the light-emitting element body 20 may be directly used as a mask, and the second light-transmitting protection layer 13 may be patterned under the mask effect of the light-emitting element body 20. The portion of the second light-transmitting protection layer 13 not covered by the light-emitting element body 20 may be removed. The portion of the second light-transmitting protection layer 13 covered by the light-emitting element body 20 may be retained to form the light-transmitting protection structure 211.

In this configuration, a mask plate does not need to be provided separately in the process of patterning the second light-transmitting protection layer 13. On the one hand, alignment error between the mask and the light-emitting element body 20 due to process deviation may be avoided, and the alignment accuracy between the light-transmitting protection structure 211 and the light-emitting element body 20 may be improved. On the other hand, the mask cost may be reduced.

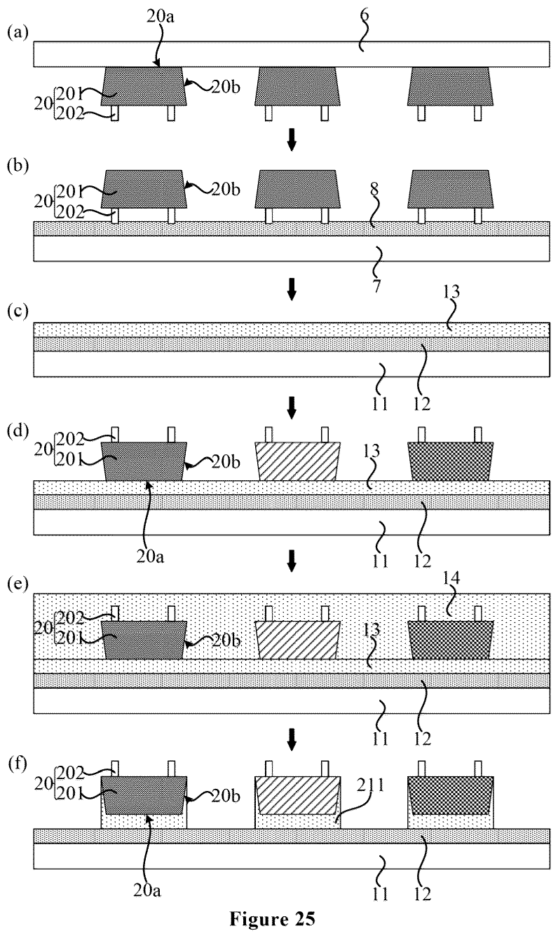

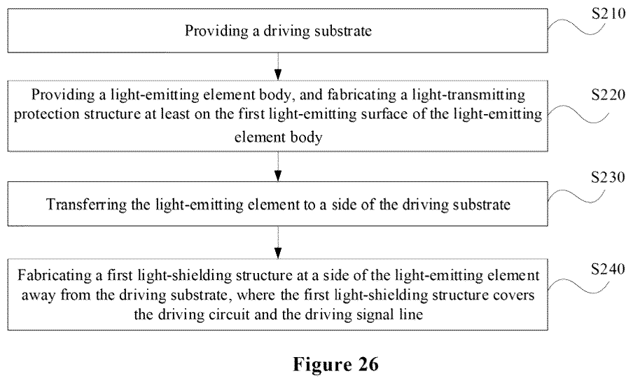

FIG. 24 illustrates a flowchart of a process for fabricating another light-transmitting protection structure, consistent with the disclosed embodiments of the present disclosure. FIG. 25 illustrates a schematic diagram of the process illustrated in FIG. 24. Referring to FIGS. 24 and 25, S120 may include S1210, S1211, S1212, S1213, S1214, and S1215.

S1210, fabricating a light-emitting element body in the supporting substrate.

S1211, providing a first transfer substrate, and transferring the light-emitting element body to the first transfer substrate in a manner that the first light-emitting surface faces away from the first transfer substrate.

S1212, providing a second transfer substrate, and fabricating a second light-transmitting protection layer on a side of the second transfer substrate.

S1213, transferring the light-emitting element body to the second transfer substrate with the first light-emitting surface facing the second light-transmitting protection layer.

For implementation of S1210-S1213, reference may be made to S1205-S1208.

S1214, fabricating a third light-transmitting protection layer on the side of the light-emitting element body away from the second transfer substrate.

Referring to FIG. 25(e), after the light-emitting element body 20 is transferred to the second transfer substrate 11, a third light-transmitting protection layer 14 may be disposed on the side of the second transfer substrate 11 facing the light-emitting element body 20. The third light-transmitting protection layer 14 covers the light-emitting element body 20 and the second light-transmitting protection layer 13. The third light-transmitting protection layer 14 and the second light-transmitting protection layer 13 may be made of a same material.

S1215, providing a second mask, and patterning the second light-transmitting protection layer and the third light-transmitting protection layer through the second mask to fabricate the light-transmitting protection structure on the first light-emitting surface and the side light-emitting surface of the light-emitting element body.

The pattern design of the second mask matches the arrangement of the light-emitting element bodies 20 on the second transfer substrate 11. Referring to FIG. 25(f), using the second mask, the second light-transmitting protection layer 13 and the third light-transmitting protection layer 14 may be patterned to remove a portion of the second light-transmitting protection layer 13 and the third light-transmitting protection layer 14 in the region where the light-emitting element body 20 is not disposed. The second light-transmitting protection layer 13 in contact with the first light-emitting surface 20a of the light-emitting element body 20 and the third light-transmitting protection layer 14 in contact with the side light-emitting surface 20b of the light-emitting element body 20 are retained. The retained second light-transmitting protection layer 13 and the retained third light-transmitting protection layer 14 form the light-transmitting protection structure 211.

In one embodiment, the light-transmitting protection structure 211 may protect the first light-emitting surface 20a and the side light-emitting surface 20b simultaneously. When the light-transmitting protection structure 211 covers the side light-emitting surface 20b, the light emitted from the side light-emitting surface 20b of the light-emitting element 2 may also be emitted through the light-transmitting protection structure 211. Accordingly, the light-emitting efficiency of the light-emitting element 2 may be improved.

Referring to FIG. 20-25, in some embodiments, S130 may include: after the transfer substrate (the first transfer substrate and/or the second transfer substrate) is aligned with the driving substrate, transferring the light-emitting element to the driving substrate in a manner that the electrode of the light-emitting element body faces the driving substrate, so as to fix the light-emitting element to the driving substrate.

The light-transmitting protection structure may be a transparent protection structure or a color-filtering protection structure. When the light-transmitting protection structure is a transparent protection structure, the transparent protection structures corresponding to the light-emitting element bodies of different colors may be same. When the light-transmitting protection structure is a color-filtering protection structure, the color-filtering protection structures corresponding to light-emitting element bodies of different colors may be different.

Optionally, in one embodiment, the driving substrate includes a driving circuit and a driving signal line. The driving circuit is electrically connected to the driving signal line and the light-emitting element body respectively. After S130 is performed, the method also includes fabricating a first light-shielding structure at a side of the light-emitting element away from the driving substrate. The first light-shielding structure covers the driving circuit and the driving signal line. The first light-shielding structure exposes the side light-emitting surface, or the first light-shielding structure covers at least a portion of the side light-emitting surface.

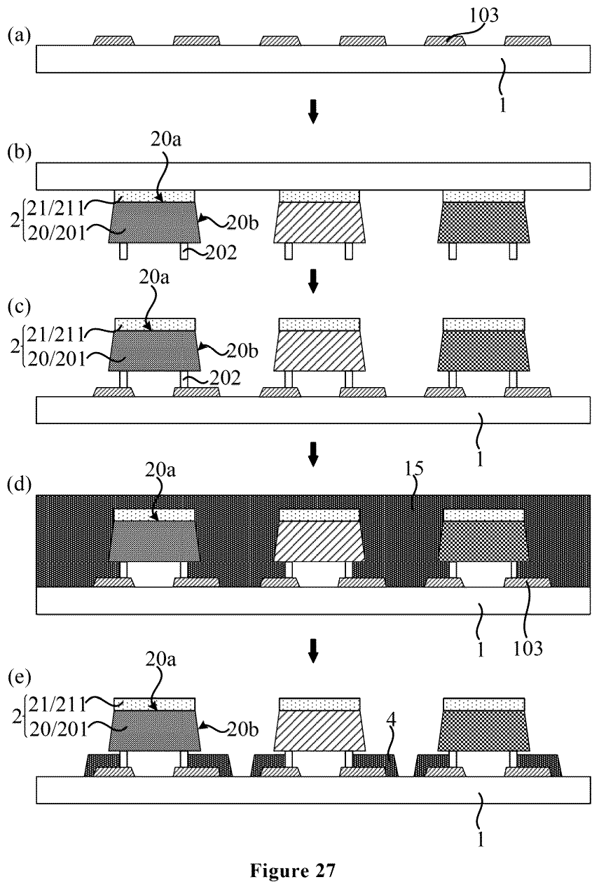

FIG. 26 illustrates a flowchart of a method for manufacturing another display panel, consistent with the disclosed embodiments of the present disclosure. FIG. 27 illustrates is a schematic diagram of the method illustrated in FIG. 26. Referring to FIGS. 26 and 27, the method includes S210, S220, S230, and S240.

S210, providing a driving substrate.

S220, providing a light-emitting element body, and fabricating a light-transmitting protection structure at least on the first light-emitting surface of the light-emitting element body.

S230, transferring the light-emitting element to a side of the driving substrate.

For implementation of S210-S230, reference may be made to the descriptions of S110, S120 and S30, which will not be elaborated here.

S240, fabricating a first light-shielding structure at a side of the light-emitting element away from the driving substrate, where the first light-shielding structure covers the driving circuit and the driving signal line.

Referring to FIGS. 27(d) and 27(e), a first initial light-shielding layer 15 may be disposed on a side of the light-emitting element 2 away from the driving substrate 1. The first initial light-shielding layer 15 covers the light-emitting element 2 and the driving substrate 1. The first initial light-shielding layer 15 may then be patterned using a fourth mask, to remove at least the first initial light-shielding layer 15 on the first light-emitting surface 20a of the light-emitting element body 20. A portion of the first initial light-shielding layer 15 covering the driving circuit (not shown in FIG. 27) and the driving signal line 103 is retained. The retained first initial light-shielding layer 15 forms the first light-shielding structure 4.

It should be noted that, when the first initial light-shielding layer 15 is patterned, the light-transmitting protection structure 211 may be damaged. As such, the thickness of the light-transmitting protection structure 211 shown in FIG. 27(e) may be smaller than the thickness of the light-transmitting protection structure 211 shown in FIG. 27(d).

The first light-shielding structure 4 may expose the side light-emitting surface 20b (as shown in FIG. 27), or the first light-shielding structure 4 may cover at least a portion of the side light-emitting surface 20b. When patterning the first initial light-shielding layer 15, the first initial light-shielding layer 15 surrounding the first light-emitting surface 20a of the light-emitting element body 20 and the side surface of the light-emitting element 2 may be removed. The retained first light-shielding structure 4 exposes the side light-emitting surface 20b. Alternatively, only the first initial light-shielding layer 15 on the first light-emitting surface 20a of the light-emitting element body 20 is removed, and thus the first light-shielding structure 4 covers the side light-emitting surface 20b.

Optionally, in some other embodiments, before transferring the light-emitting element to a side of the driving substrate, the method also includes: providing a light-emitting element body, and fabricating a light-shielding protection structure on the side light-emitting surface of the light-emitting element body.

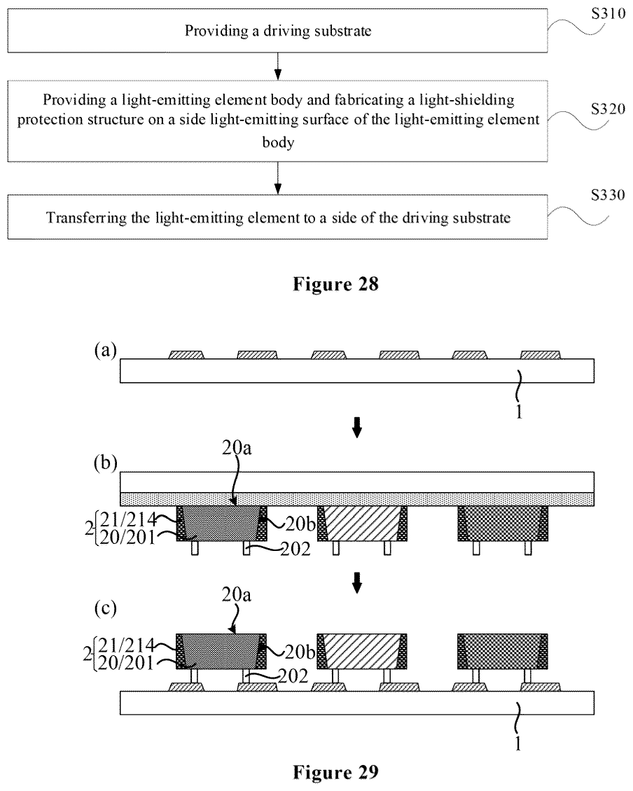

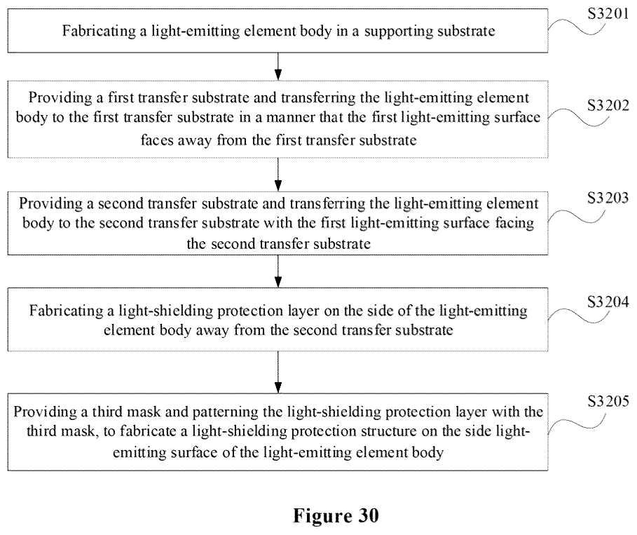

FIG. 28 illustrates a flowchart of a method for manufacturing another display panel, consistent with the disclosed embodiments of the present disclosure. FIG. 29 illustrates a schematic diagram of the method illustrated in FIG. 28. Referring to FIGS. 28 and 29, the method may specifically include S310, S320 and S330.

S310, providing a driving substrate.

S320, providing a light-emitting element body and fabricating a light-shielding protection structure on a side light-emitting surface of the light-emitting element body.

As shown in FIG. 29(b), a light-shielding protection structure 214 may be disposed on at least a portion of the side light-emitting surface 20b of the light-emitting element body 20. The light-shielding protection structure 214 may be made of a light-shielding material. The light-shielding protection structure 214 may be disposed in one-to-one correspondence with the light-emitting element body 20.

S330, transferring the light-emitting element to a side of the driving substrate.

By fabricating the light-shielding protection structure on the side light-emitting surface of the light-emitting element body, the light-shielding protection structure may block the side light of the light-emitting element, such that the light is emitted from the first light-emitting surface. Accordingly, the problem of large visual angle deviation caused by side light may be eased. In addition, after the light-emitting element body is transferred to the driving substrate, no additional light-shielding layer needs to be disposed. As a result, in addition to keeping the light-emitting efficiency of the light-emitting element, the process of fabricating and patterning the light-shielding layer may be omitted. As such, the manufacturing process may be simplified, and problems of light-shielding material remaining on the first light-emitting surface and damage to the light-emitting element may be avoided.

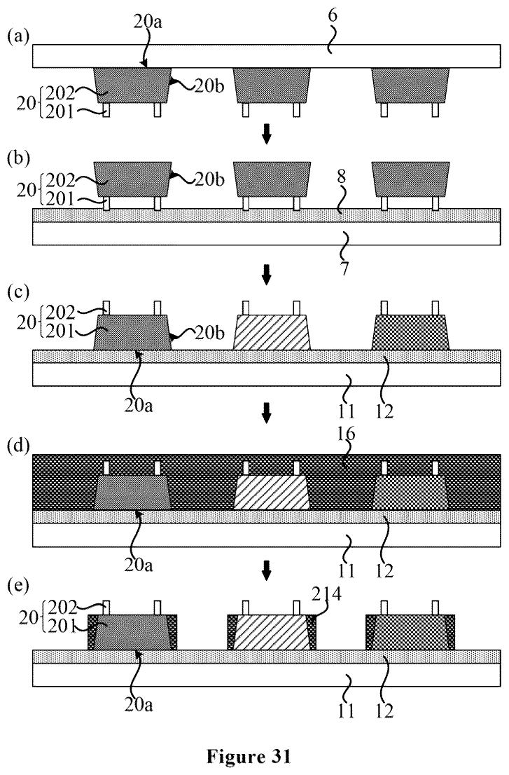

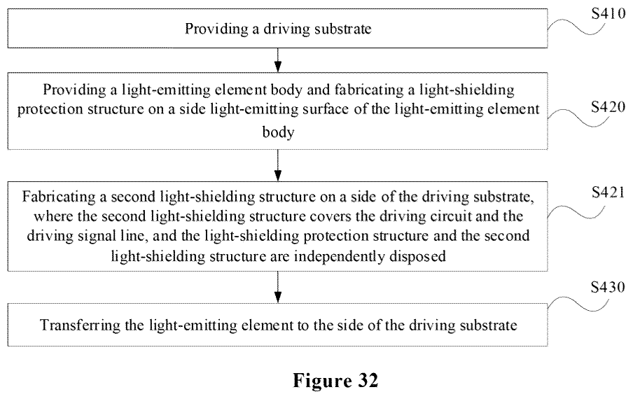

FIG. 30 illustrates a flowchart of a process for fabricating a light-shielding protection structure consistent with the disclosed embodiments of the present disclosure. FIG. 31 illustrates a schematic diagram of the process illustrated in FIG. 30. Referring to FIGS. 30 and 31, S320 may include S3201, S3202, S3203, S3204 and S3205.

S3201, fabricating a light-emitting element body in a supporting substrate.

S3202, providing a first transfer substrate, and transferring the light-emitting element body to the first transfer substrate in a manner that the first light-emitting surface faces away from the first transfer substrate.

For implementation of S3201 and S3202, reference may be made to the descriptions of S1210 and S1211, which will not be elaborated here.

S3203, providing a second transfer substrate, and transferring the light-emitting element body to the second transfer substrate with the first light-emitting surface facing the second transfer substrate.

As shown in FIG. 31(c), a second transfer substrate 11 is provided. A second release adhesive layer 12 may be disposed on a side of the second transfer substrate 11. After the first transfer substrate 7 is aligned with the second transfer substrate 11, the light-emitting element body 20 on the first transfer substrate may be transferred to the second transfer substrate 11. The first light-emitting surface 20a of the light-emitting element body 20 may be fixed to the second release adhesive layer 12.

S3204, fabricating a light-shielding protection layer on the side of the light-emitting element body away from the second transfer substrate.

Referring to FIG. 31(d), the light-shielding protection layer 16 may be fabricated by evaporation or the like. The light-shielding protection layer 16 covers the light-emitting element bodies 20 and the second release adhesive layer 12 exposed between adjacent light-emitting element bodies 20. The light-shielding protection layer 16 may be made of a black material, such as a carbon black system material, but is not limited thereto.

S3205, providing a third mask, and patterning the light-shielding protection layer with the third mask, to fabricate a light-shielding protection structure on the side light-emitting surface of the light-emitting element body.

The pattern design of the third mask matches the arrangement of the side light-emitting surface 20b of the light-emitting element body 20 on the second transfer substrate 11. Referring to FIG. 31(e), the light-shielding protection layer 16 is patterned using the third mask. The light-shielding protection layer 16 over the first light-emitting surface 20a of the light-emitting element body 20 and the portion of the light-shielding protection layer 16 between the side light-emitting surfaces 20b of two adjacent light-emitting element bodies 20 may be removed. The light-shielding protection layer 16 covering the side light-emitting surface 20b of the light-emitting element body 20 may be retained, and the retained portion of the light-shielding protection layer 16 forms the light-shielding protection structure 214.

Optionally, the driving substrate may include a driving circuit and a driving signal line. The driving circuit may be electrically connected to the driving signal line and the light-emitting element body respectively. Before S330, the method may also include: fabricating a second light-shielding structure on a side of the driving substrate. The second light-shielding structure may cover the driving circuit and the driving signal line, and the light-shielding protection structure and the second light-shielding structure may be independently disposed.

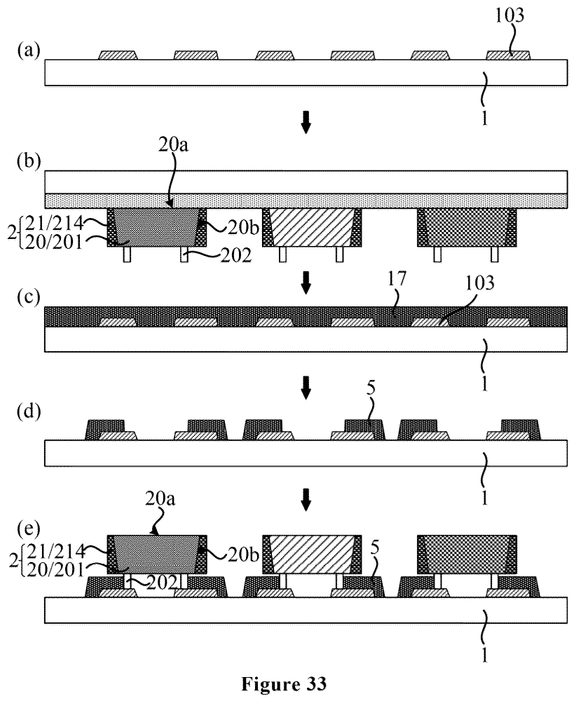

FIG. 32 illustrates a flowchart of a method for manufacturing another display panel, consistent with the disclosed embodiments of the present disclosure. FIG. 33 illustrates a schematic diagram of the method illustrated in FIG. 32. Referring to FIGS. 32 and 33, in one embodiment, the method includes S410, S420, S421, and S430.

S410, providing a driving substrate.

S420, providing a light-emitting element body, and fabricating a light-shielding protection structure on a side light-emitting surface of the light-emitting element body.

S421, fabricating a second light-shielding structure on a side of the driving substrate. The second light-shielding structure covers the driving circuit and the driving signal line, and the light-shielding protection structure and the second light-shielding structure are independently disposed.

As shown in FIGS. 33(c) and 33(d), a whole layer of second initial light-shielding layer 17 may be disposed on a side of the driving substrate 1 by using a process such as evaporation. Then, the second initial light-shielding layer 17 may be patterned using a fifth mask to remove at least a portion of the second initial light-shielding layer 17 that overlaps with the driving circuit (not shown in FIG. 33) and the driving signal line 103. A portion of the second initial light-shielding layer 17 covering the driving circuit and the driving signal line 103 may be retained, and the retained second initial light-shielding layer 17 forms the second light-shielding structure 5. The light-shielding protection structure 214 and the second light-shielding structure 5 are not in contact with each other, and are independent of each other.

In one embodiment, S421 may be performed after S420 and before S430, or after S410 and before S420, and the present disclosure does not limit a specific operation sequence.

S430, transferring the light-emitting element to the side of the driving substrate.

In the present disclosure, the light-emitting element bodies in the drawings corresponding to some embodiments are in an inverted trapezoidal shape, and the light-emitting element bodies in the drawings corresponding to some other embodiments are in a regular trapezoidal shape. The shape of the light-emitting element body in the present disclosure is only an example and is not intended to limit the present disclosure.

The method for manufacturing a display panel provided by the present disclosure includes technical features and corresponding beneficial effects of the display panel provided by the present disclosure. For details of the method not elaborated in the present disclosure, reference may be made to corresponding embodiments of the display panel in the present disclosure.

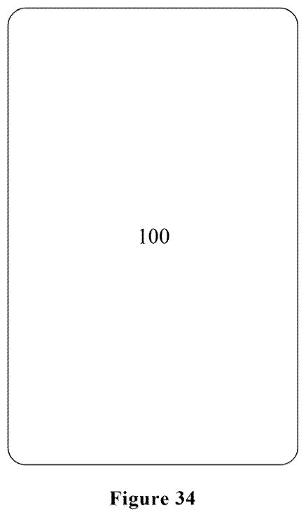

The present disclosure also provides a display device. FIG. 34 illustrates a schematic structural diagram of a display device consistent with the disclosed embodiments of the present disclosure. As shown in FIG. 34, the display device includes a display panel 100 provided by the present disclosure. The display device provided by the present disclosure may have corresponding beneficial effects of the display panel provided by the present disclosure, which will not be elaborated here. Exemplarily, the display device may be an electronic device such as a mobile phone, a computer, a smart wearable device (e.g., a smart watch), or a vehicle-mounted display device, and the present disclosure is not limited thereto.

As disclosed, the technical solutions of the present disclosure have the following advantages.

In the present disclosure, the light-emitting element includes a light-emitting element body and a protection structure. The protection structure contacts and covers the light-emitting surface of the light-emitting element body. The light-emitting surface includes a first light-emitting surface and/or a side light-emitting surface. The protection structure may protect the light-emitting element body, and the problem of light-shielding material remaining on the first light-emitting surface of the light-emitting element body may be avoided. As such, the light-emitting efficiency of the light-emitting component may be improved, and the display effect of the display panel may be improved. In addition, the protection structures of at least a portion of the light-emitting elements are independently disposed. The protection structure may protect the light-emitting element body corresponding to the protection structure. As such, when etching the light-shielding material, damage to the light-emitting surface of the light-emitting element may be reduced or even avoided. Accordingly, the light-emitting effect and light-emitting efficiency of the light-emitting element body may be improved.

The embodiments disclosed herein are exemplary only and not limiting the scope of the present disclosure. Various combinations, alternations, modifications, equivalents, or improvements to the technical solutions of the disclosed embodiments may be obvious to those skilled in the art. Without departing from the spirit and scope of this disclosure, such combinations, alternations, modifications, equivalents, or improvements to the disclosed embodiments are encompassed within the scope of the present disclosure.

What is claimed is:

1. A display panel, comprising a driving substrate and a light-emitting element disposed on a side of the driving substrate, wherein:
the light-emitting element includes a light-emitting element body and a protection structure, wherein the protection structure contacts and covers a light-emitting surface of the light-emitting element body;
the light-emitting surface includes a first light-emitting surface and/or a side light-emitting surface, wherein the first light-emitting surface is a surface of the light-emitting element body away from the driving substrate;
a plane where the side light-emitting surface is located intersects with a plane where the first light-emitting surface is located; and
the protection structures of at least a portion of the light-emitting elements are independently disposed.

2. The display panel according to claim 1, wherein:
the protection structure includes a light-transmitting protection structure, wherein the light-transmitting protection structure at least covers the first light-emitting surface.

3. The display panel according to claim 2, wherein:
a refractive index of the light-transmitting protection structure is smaller than a refractive index of the light-emitting element body.

4. The display panel according to claim 3, wherein:
the light-emitting element body includes a first color light-emitting element body, a second color light-emitting element body and a third color light-emitting element body, wherein a refractive index of the first color light-emitting element body is greater than a refractive index of the second color light-emitting element body and/or a refractive index of the third color light-emitting element body; the light-transmitting protection structure includes a first protection structure, a second protection structure and a third protection structure, wherein the first protection structure contacts and covers a light-emitting surface of the first color light-emitting element body, the second protection structure contacts and covers a light-emitting surface of the second color light-emitting element body, and the third protection structure contacts and covers a light-emitting surface of the third color light-emitting element body; and a refractive index of the first protection structure is greater than a refractive index of the second protection structure and/or a refractive index of the third protection structure;
and/or
the display panel further comprises an encapsulation layer disposed on a side of the light-transmitting protection structure away from the driving substrate, wherein the refractive index of the light-transmitting protection structure is greater than a refractive index of the encapsulation layer.

5. The display panel according to claim 2, further comprising an encapsulation layer disposed on a side of the light-transmitting protection structure away from the driving substrate, wherein:
the light-transmitting protection structure and the encapsulation layer are made of different materials.

6. The display panel according to claim 2, wherein:
the light-transmitting protection structure includes a first position and a second position, wherein, along a thickness direction of the display panel, a thickness of the light-transmitting protection structure at the first position is not equal to a thickness of the light-transmitting protection structure at the second position.

7. The display panel according to claim 2, wherein:
the light-transmitting protection structure includes a transparent protection structure; or
the light-transmitting protection structure includes a color-filtering protection structure.

8. The display panel according to claim 2, wherein:
the light-transmitting protection structure covers the first light-emitting surface and the side light-emitting surface.

9. The display panel according to claim 2, further comprising a first light-shielding structure, wherein:
the driving substrate includes a driving circuit and a driving signal line, wherein the driving circuit is electrically connected to the driving signal line and the light-emitting element respectively;
the first light-shielding structure covers the driving circuit and the driving signal line; and
the first light-shielding structure exposes the side light-emitting surface, or the first light-shielding structure covers at least a portion of the side light-emitting surface.

10. The display panel according to claim 1, wherein:
the protection structure includes a light-shielding protection structure, wherein the light-shielding protection structure covers the side light-emitting surface.

11. The display panel according to claim 10, further comprising a second light-shielding structure, wherein:
the driving substrate includes a driving circuit and a driving signal line, wherein the driving circuit is electrically connected to the driving signal line and the light-emitting element respectively;
the second light-shielding structure covers the driving circuit and the driving signal line; and
the light-shielding protection structure and the second light-shielding structure are independently disposed.

12. The display panel according to claim 1, wherein:
the first light-emitting surface includes a plurality of microstructures; and/or
the light-emitting surface further includes a second light-emitting surface, wherein the second light-emitting surface is located on a side of the first light-emitting surface close to the driving substrate; and along a thickness direction of the display panel, the first light-emitting surface covers the second light-emitting surface, or the second light-emitting surface covers the first light-emitting surface.

13. A method for manufacturing a display panel, comprising providing a driving substrate, and transferring a light-emitting element to a side of the driving substrate, wherein:
the light-emitting element includes a light-emitting element body and a protection structure, wherein the protection structure contacts and covers a light-emitting surface of the light-emitting element body;
the light-emitting surface includes a first light-emitting surface and/or a side light-emitting surface, wherein the first light-emitting surface is a surface of the light-emitting element body away from the driving substrate;
a plane where the side light-emitting surface is located intersects with a plane where the first light-emitting surface is located; and
the protection structures of at least a portion of the light-emitting elements are independently disposed.

14. The method according to claim 13, before transferring the light-emitting element to a side of the driving substrate, further comprising:
providing the light-emitting element body and disposing a light-transmitting protection structure of the protection structure at least over the first light-emitting surface of the light-emitting element body.

15. The method according to claim 14, wherein providing the light-emitting element body and disposing the light-transmitting protection structure at least over the first light-emitting surface of the light-emitting element body includes:
fabricating the light-emitting element body in a supporting substrate; providing a first transfer substrate and transferring the light-emitting element body to the first transfer substrate in a manner that the first light-emitting surface faces away from the first transfer substrate;
fabricating a first light-transmitting protection layer at least on a side of the light-emitting element body away from the first transfer substrate; and providing a first mask and patterning the first light-transmitting protection layer through the first mask to fabricate the light-transmitting protection structure over the first light-emitting surface of the light-emitting element body; or
fabricating the light-emitting element body in a supporting substrate; providing a first transfer substrate and transferring the light-emitting element body to the first transfer substrate in a manner that the first light-emitting surface faces away from the first transfer substrate; providing a second transfer substrate and disposing a second light-transmitting protection layer on a side of the second transfer substrate; transferring the light-emitting element body to the second transfer substrate with the first light-emitting surface facing the second light-transmitting protection layer; and with the light-emitting element body as a mask, patterning the second light-transmitting protection layer to fabricate the light-transmitting protection structure over the first light-emitting surface of the light-emitting element body; or
fabricating the light-emitting element body in a supporting substrate; providing a first transfer substrate, and transferring the light-emitting element body to the first transfer substrate in a manner that the first light-emitting surface faces away from the first transfer substrate; providing a second transfer substrate, and disposing a second light-transmitting protection layer on a side of the second transfer substrate; transferring the light-emitting element body to the second transfer substrate with the first light-emitting surface facing the second light-transmitting protection layer; disposing a third light-transmitting protection layer on a side of the light-emitting element body away from the second transfer substrate; and providing a second mask and patterning the second light-transmitting protection layer and the third light-transmitting protection layer through the second mask to fabricate the light-transmitting protection structure over the first light-emitting surface and the side light-emitting surface of the light-emitting element body.

16. The method according to claim 14, after transferring the light-emitting element to a side of the driving substrate, further comprising fabricating a first light-shielding structure at a side of the light-emitting element away from the driving substrate, wherein:
the driving substrate includes a driving circuit and a driving signal line, wherein the driving circuit is electrically connected to the driving signal line and the light-emitting element body respectively;
the first light-shielding structure covers the driving circuit and the driving signal line; and
the first light-shielding structure exposes the side light-emitting surface, or the first light-shielding structure covers at least a portion of the side light-emitting surface.

17. The method according to claim 13, before transferring the light-emitting element to a side of the driving substrate, further comprising:
providing the light-emitting element body and fabricating a light-shielding protection structure on the side light-emitting surface of the light-emitting element body.

18. The method according to claim 17, wherein providing the light-emitting element body and fabricating the light-shielding protection structure on the side light-emitting surface of the light-emitting element body includes:
fabricating the light-emitting element body in a supporting substrate;
providing a first transfer substrate, and transferring the light-emitting element body to the first transfer substrate in a manner that the first light-emitting surface faces away from the first transfer substrate;
providing a second transfer substrate, and transferring the light-emitting element body to the second transfer substrate with the first light-emitting surface facing the second transfer substrate;
fabricating a light-shielding protection layer on a side of the light-emitting element body away from the second transfer substrate; and
providing a third mask and patterning the light-shielding protection layer with the third mask, to fabricate the light-shielding protection structure on the side light-emitting surface of the light-emitting element body.

19. The method according to claim 18, before transferring the light-emitting element to a side of the driving substrate, further comprising fabricating a second light-shielding structure on the side of the driving substrate, wherein:
the driving substrate includes a driving circuit and a driving signal line, wherein the driving circuit is electrically connected to the driving signal line and the light-emitting element body respectively; and
the second light-shielding structure covers the driving circuit and the driving signal line, and the light-shielding protection structure and the second light-shielding structure are independently disposed.

20. A display device, comprising a display panel, wherein the display panel includes a driving substrate and a light-emitting element disposed on a side of the driving substrate, wherein:
the light-emitting element includes a light-emitting element body and a protection structure, wherein the protection structure contacts and covers a light-emitting surface of the light-emitting element body;
the light-emitting surface includes a first light-emitting surface and/or a side light-emitting surface, wherein the first light-emitting surface is a surface of the light-emitting element body away from the driving substrate;
a plane where the side light-emitting surface is located intersects with a plane where the first light-emitting surface is located; and
the protection structures of at least a portion of the light-emitting elements are independently disposed.
